(19) United States
(12) Patent Application Publication
(10) Pub. No.: US 2026/0101537 A1
(43) Pub. Date: Apr. 9, 2026

(54) TRANSISTOR STRUCTURE HAVING INCREASED SOURCE/DRAIN CURRENT AND METHOD OF MANUFACTURING THEREOF

(71) Applicant: Taiwan Semiconductor Manufacturing Company, Ltd., Hsinchu (TW)

(72) Inventor: Tzu-Ging LIN, Hsinchu (TW)

(73) Assignee: Taiwan Semiconductor Manufacturing Company, Ltd., Hsinchu (TW)

(21) Appl. No.: 18/907,514

(22) Filed: Oct. 5, 2024

(51) Int. Cl. H01L 29/423; H01L 29/06; H01L 29/66; H01L 29/775; H01L 29/786

(52) U.S. Cl. CPC H10D 30/6735; H10D 30/014; H10D 30/43; H10D 30/6757; H10D 62/121; H10D 64/017

(57) ABSTRACT

A method of manufacturing a semiconductor device includes forming an alternating layer stack including first semiconductor layers and second semiconductor layers stacked along a first direction that is perpendicular to interfaces of the alternating layer stack. The alternating layer stack is patterned to form a fin structure having a height along the first direction, a length along a second direction that is perpendicular to the first direction, and a width along a third direction that is perpendicular to the first direction and the second direction. The fin structure is patterned to generate source/drain regions that are separated from one another along the second direction. The first semiconductor layers are removed and a dielectric interposer layer are formed within spaces between adjacent second semiconductor layers previously occupied by the first semiconductor layers. The method further includes forming source/drain epitaxial layers and performing an annealing operation after forming the source/drain epitaxial layers.

### BACKGROUND

As the semiconductor industry advances into nanometer-scale technology nodes, driven by the need for higher device density, enhanced performance, and reduced costs, it has faced significant fabrication and design challenges. These challenges have led to the adoption of three-dimensional structures, such as multi-gate field-effect transistors (FETs), including fin field-effect transistors (FinFETs), and gate-all-around field-effect transistors (GAA-FETs). In a FinFET, the gate electrode interfaces with three sides of the channel region, separated by a gate dielectric layer. This configuration effectively provides control over the current flow through the channel, as the gate wraps around three of the channel's surfaces. However, the fourth side, which forms the bottom of the channel, remains distant from the gate electrode and thus experiences less effective gate control. In contrast, a GAA-FET features a gate electrode that surrounds all sides of the channel region, enabling more comprehensive depletion of the channel and resulting in reduced short-channel effects due to a steeper subthreshold swing and lower drain-induced barrier lowering. As transistor dimensions continue to shrink, further advancements in GAA-FET technology are necessary to meet the increasing demands of modern semiconductor devices.

### BRIEF DESCRIPTION OF THE DRAWINGS

The present disclosure is best understood from the following detailed description when read with the accompanying figures. It is emphasized that, per the standard practice in the industry, various features are not drawn to scale and are used for illustration purposes only. The dimensions of the various features may be arbitrarily increased or reduced for clarity of discussion.

FIG. 1 is a vertical cross-sectional view of a semiconductor device configured as a gate-all-around field-effect transistor (GAA FET) according to various embodiments.

FIG. 2A is a vertical cross-sectional view of an intermediate structure that may be used in the formation of a semiconductor device according to a comparative embodiment.

FIG. 2B is a vertical cross-sectional view of a semiconductor layer of the intermediate structure of FIG. 2A after performing an annealing operation.

FIG. 2C is a vertical cross-sectional view of surface roughness that may occur in the intermediate structure of FIG. 2A.

FIG. 2D is an energy band-structure diagram showing surface-induced changes due to intermixing of semiconductor materials at interfaces of the semiconductor layer of FIGS. 2A and 2B.

FIG. 3A is a vertical cross-sectional view of a semiconductor device having defective interfaces, according to a comparative embodiment.

FIG. 3B is an expanded vertical cross-sectional view of a portion of the semiconductor device of FIG. 3A.

FIG. 3C is an expanded vertical cross-sectional view of a further portion of the semiconductor device of FIG. 3A.

FIG. 4A is a vertical cross-sectional view of an intermediate structure that may be used in the formation of a semiconductor device according to various embodiments.

FIG. 4B is a vertical cross-sectional view of a semiconductor device according to various embodiments.

FIG. 4C is a vertical cross-sectional view of a further semiconductor device according to various embodiments.

FIG. 4D is a vertical cross-sectional view of a further semiconductor device according to various embodiments.

FIG. 5A is a vertical cross-sectional view of an intermediate structure used to form a semiconductor device according to various embodiments.

FIG. 5B is a further vertical cross-sectional view of the intermediate structure of FIG. 5A according to various embodiments.

FIG. 6A is a vertical cross-sectional view of a further intermediate structure that may be used to form a semiconductor device according to various embodiments.

FIG. 6B is a further vertical cross-sectional view of the intermediate structure of FIG. 6A according to various embodiments.

FIG. 7A is a vertical cross-sectional view of a further intermediate structure used to form a semiconductor device according to various embodiments.

FIG. 7B is a further vertical cross-sectional view of the intermediate structure of FIG. 7A according to various embodiments.

FIG. 8A is a vertical cross-sectional view of a further intermediate structure used to form a semiconductor device according to various embodiments.

FIG. 8B is a further vertical cross-sectional view of the intermediate structure of FIG. 8A according to various embodiments.

FIG. 9A is a vertical cross-sectional view of a further intermediate structure used to form a semiconductor device according to various embodiments.

FIG. 9B is a further vertical cross-sectional view of the intermediate structure of FIG. 9A according to various embodiments.

FIG. 10A is a vertical cross-sectional view of a further intermediate structure used to form a semiconductor device according to various embodiments.

FIG. 10B is a further vertical cross-sectional view of the intermediate structure of FIG. 10A according to various embodiments.

FIG. 11A is a vertical cross-sectional view of a further intermediate structure used to form a semiconductor device according to various embodiments.

FIG. 11B is a further vertical cross-sectional view of the intermediate structure of FIG. 11A according to various embodiments.

FIG. 12A is a vertical cross-sectional view of a further intermediate structure used to form a semiconductor device according to various embodiments.

FIG. 12B is a further vertical cross-sectional view of the intermediate structure of FIG. 12A according to various embodiments.

FIG. 13A is a vertical cross-sectional view of a further intermediate structure used to form a semiconductor device according to various embodiments.

FIG. 13B is a further vertical cross-sectional view of the intermediate structure of FIG. 13A according to various embodiments.

FIG. 14A is a vertical cross-sectional view of a further intermediate structure used to form a semiconductor device, according to various embodiments.

FIG. 14B is a further vertical cross-sectional view of the intermediate structure of FIG. 14A according to various embodiments.

FIG. 15A is a vertical cross-sectional view of a further intermediate structure used to form a semiconductor device, according to various embodiments.

FIG. 15B is a further vertical cross-sectional view of the intermediate structure of FIG. 15A according to various embodiments.

FIG. 16A is a vertical cross-sectional view of a further intermediate structure used to form a semiconductor device, according to various embodiments.

FIG. 16B is a further vertical cross-sectional view of the intermediate structure of FIG. 16A according to various embodiments.

FIG. 17A is a vertical cross-sectional view of a further intermediate structure used to form a semiconductor device, according to various embodiments.

FIG. 17B is a further vertical cross-sectional view of the intermediate structure of FIG. 17A according to various embodiments.

FIG. 18A is a vertical cross-sectional view of a further intermediate structure used to form a semiconductor device, according to various embodiments.

FIG. 18B is a further vertical cross-sectional view of the intermediate structure of FIG. 18A according to various embodiments.

FIG. 19 is a flowchart illustrating operations of a semiconductor device manufacturing method according to various embodiments.

FIG. 20 is a flowchart illustrating operations of a semiconductor device manufacturing method according to various embodiments.

### DETAILED DESCRIPTION

It is to be understood that the following disclosure provides many different embodiments, or examples, for implementing different features of the invention. Specific embodiments or examples of components and arrangements are described below to simplify the present disclosure. These are, of course, merely examples and are not intended to be limiting. For example, dimensions of elements are not limited to the disclosed range or values but may depend upon process conditions and/or desired properties of the device. Moreover, the formation of a first feature over or on a second feature in the description that follows may include embodiments in which the first and second features are formed in direct contact, and may also include embodiments in which additional features may be formed by interposing the first and second features, such that the first and second features may not be in direct contact. Various features may be arbitrarily drawn in different scales for simplicity and clarity.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In addition, the term “being made of” may mean either “comprising” or “consisting of.” In the present disclosure, the phrase “one of A, B and C” means “A, B and/or C” (A, B, C, A and B, A and C, B and C, or A, B and C), and does not mean one element from A, one element from B and one element from C, unless otherwise described.

Disclosed embodiments are advantageous by providing a gate-all-around field-effect transistor (GAA-FET) including stacked channel regions having a high degree of thickness uniformity and smooth interfaces between the stacked channel regions and adjacent portions of a gate structure. The high degree of thickness uniformity leads to improved device performance including increased source/drain current and reduced ohmic loss relative to comparative embodiments that have reduced-quality interfaces. The superior quality of the stacked channel regions results from a manufacturing process in which a sacrificial semiconductor layer, located between adjacent channel regions, is removed, and replaced with a dielectric interposer layer before any annealing processes are performed. After subsequent processing operations, including formation of source/drain epitaxial layers followed by annealing operations, the dielectric interposer layer is removed and the gate structure is formed in spaces previously occupied by the dielectric interposer layer.

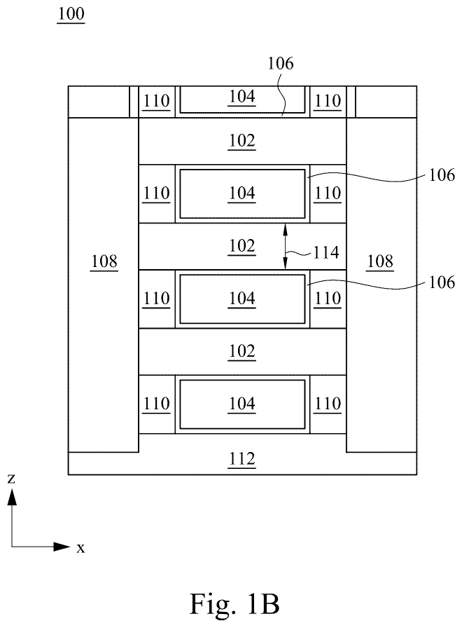

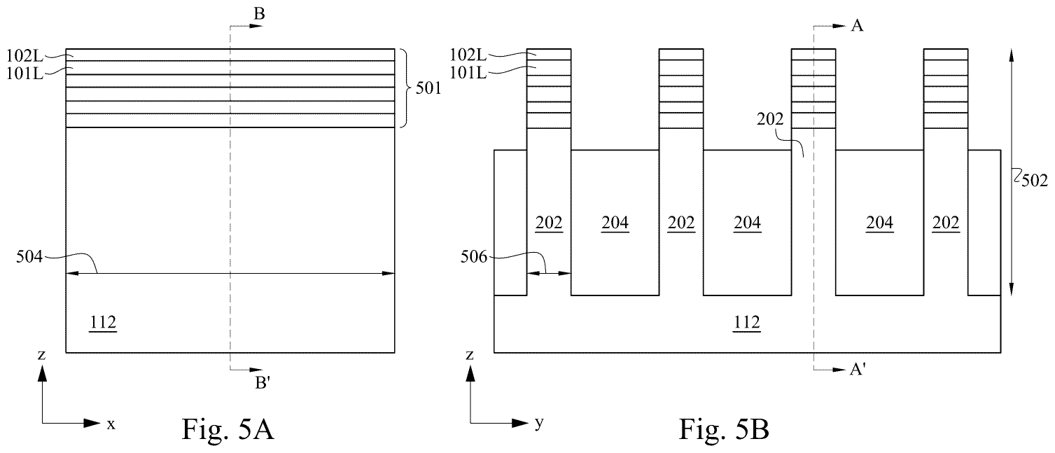

FIG. 1 is a vertical cross-sectional view of a semiconductor device 100 configured as a GAA-FET, according to various embodiments. The semiconductor device 100 includes a plurality of semiconductor layers stacked along a thickness direction (i.e., the z-direction) and configured as stacked channel regions 102. The semiconductor device 100 further includes a gate structure 104 surrounding each of the stacked channel regions 102. The gate structure 104 includes an electrically conductive material that is separated from the stacked channel regions 102 by a gate dielectric layer 106. The semiconductor device 100 further includes source/drain epitaxial layers 108 formed on opposite ends of the stacked channel regions 102 along a width direction (i.e., the x-direction) and a plurality of dielectric spacers 110 that electrically separate the gate structure 104 from the source/drain epitaxial layers 108. In various embodiments, the semiconductor device 100 is formed in a fin structure over a semiconductor substrate 112, as described in greater detail with reference to FIGS. 5A to 18B, below.

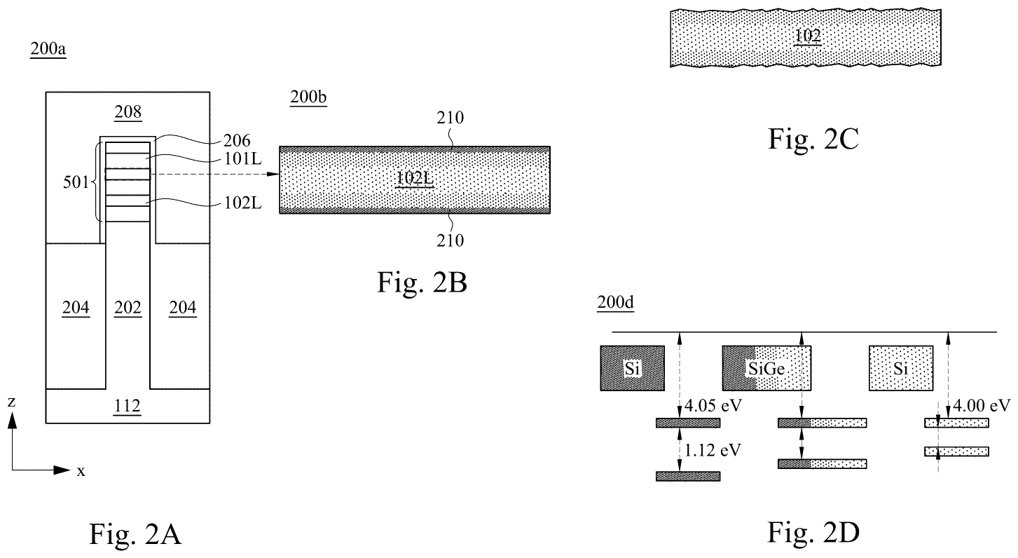

According to various embodiments, the semiconductor device 100 includes stacked channel regions 102 having a high degree of thickness uniformity with smooth interfaces between the stacked channel regions 102 and adjacent portions of the gate structure 104, as described above. In this regard, each of the stacked channel regions 102 has a channel thickness 114 that is greater than 5 nm and a thickness variation that is less than 1 nm. In contrast, low-quality interfaces may be generated in comparative embodiments, if one or more annealing processes are performed before removal of a sacrificial semiconductor layer, as described in greater detail with reference to FIGS. 2A to 2D, below.

FIG. 2A is a vertical cross-sectional view of an intermediate structure 200a that may be used in the formation of a semiconductor device, according to a comparative embodiment.

The intermediate structure 200a includes a fin structure 202 formed over a semiconductor substrate 112 and partially covered by a shallow trench isolation structure 204. The intermediate structure 200a includes an alternating layer stack 501 that includes first semiconductor layers 101L and second semiconductor layers 102L stacked along the thickness direction (i.e., the z-direction). The intermediate structure 200a further includes a sacrificial gate structure (206, 208) including a sacrificial gate dielectric layer 206 and a sacrificial gate electrode layer 208.

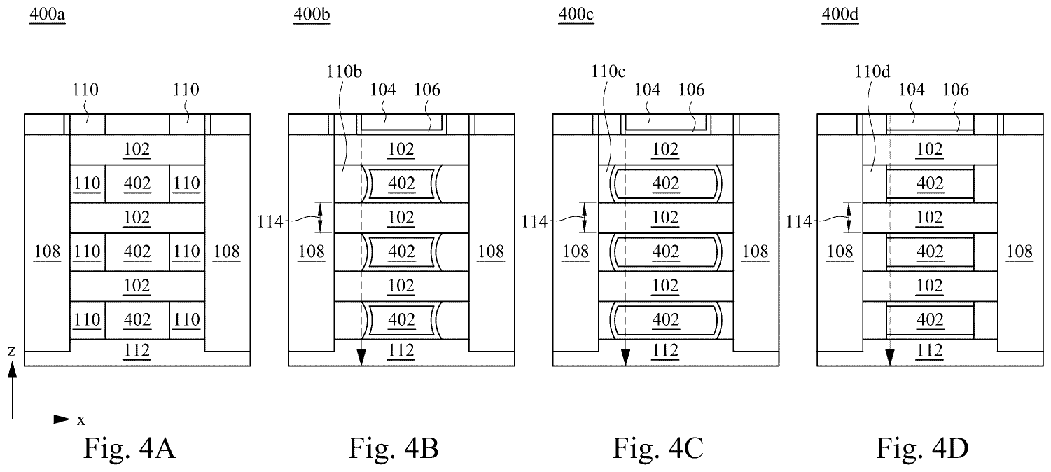

The first semiconductor layers 101L may be formed of a first semiconductor (e.g., SiGe), and the second semiconductor layers 102L may be formed of a second semiconductor (e.g., Si). The first semiconductor layers 101L may be configured as a sacrificial semiconductor layer that may be selectively removed to generate spaces (not shown) between the second semiconductor layers 102L where the gate structure 104 may be subsequently formed. As mentioned above, higher-quality interfaces may be formed if the first semiconductor layers 101L are removed and replaced by a dielectric interposer layer 402 (e.g., see FIG. 4A) before any annealing operations are performed. In contrast, however, surface roughness, alloy formation, and otherwise defective interfaces may occur if annealing processes are performed before the removal of the first semiconductor layers 101L in comparative embodiments, as described in greater detail with reference to FIGS. 2A to 2D.

FIG. 2B is a vertical cross-sectional view of one of the second semiconductor layers 102L of the intermediate structure of FIG. 2A after an annealing process is performed, and FIG. 2C is a vertical cross-sectional view of surface roughness that may occur in a channel region 102 of the intermediate structure of FIG. 2A after removal of the first semiconductor layers 101L. In this regard, if an annealing process is performed before removing the first semiconductor layers 101L, intermixing may occur between the first semiconductor layers 101L and the second semiconductor layers 102L giving rise to alloy regions 210 at surfaces of the second semiconductor layers 102L that come in contact with the first semiconductor layers 101L. For example, if the first semiconductor layers 101L are formed of SiGe and the second semiconductor layers 102L are formed of Si, then the alloy region 210 may be a SiₓGe₁₋ₓ alloy, where x represents the fraction of Si in the alloy.

An etching operation subsequently performed to selectively remove the first semiconductor layers 101L may also remove a portion of the alloy region 210 giving rise to surface roughness of the resulting channel region 102, as shown in FIG. 2C. Such surface roughness may be a source of carrier scattering that may generate ohmic loss leading to reduced source/drain current. The surface roughness indicated in FIG. 2C may also cause reduced-quality interfaces between the stacked channel regions 102, the gate dielectric layer 106, and the gate structure 104. Such reduced-quality interfaces may lead to unintended electric field screening that may cause current-voltage relationships to deviate from design specifications.

FIG. 2D is an energy band-structure diagram 200d showing surface-induced changes due to intermixing of semiconductor materials at interfaces of the semiconductor layer of FIGS. 2A and 2B. In this example, the first semiconductor layers 101L are assumed to be SiGe, and the second semiconductor layers 102L are assumed to be Si. The energy band structure for Ge is included for reference. The energy band-structure diagram 200d indicates that the alloy region 210 of FIG. 2B may have energy bands that deviate from design specifications. Such deviations, even in the absence of the surface roughness shown in FIG. 2C may lead to degradation of device performance in the form of unintended changes to current-voltage relationships relative to design specifications.

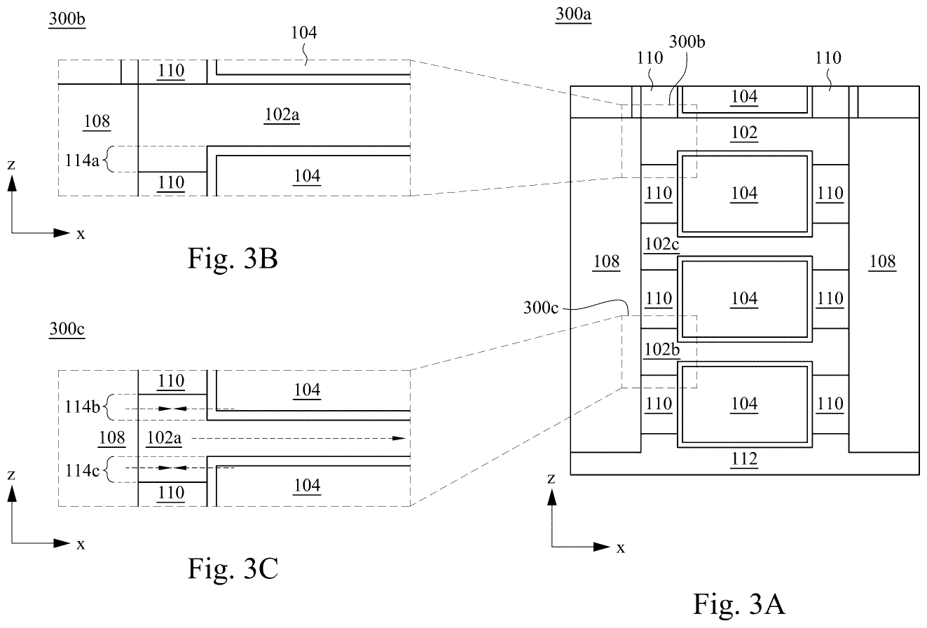

FIG. 3A is a vertical cross-sectional view of a semiconductor device 300a having defective interfaces, according to a comparative embodiment. FIG. 3B is an expanded vertical cross-sectional view of a portion 300b of the semiconductor device of FIG. 3A and FIG. 3C is an expanded vertical cross-sectional view of a further portion 300c of the semiconductor device of FIG. 3A. As described above with reference to FIG. 2C, a thickness (114a, 114b) of the stacked channel regions 102 may be reduced when an etching operation is performed to remove the first semiconductor layers 101L due to the presence of the alloy region 210 in comparative embodiments.

Thus, for example, a thickness 114a of a central region of a first channel region 102a may be reduced relative to that of end portions (e.g., end portions vertically sandwiched between dielectric spacers 110), as shown in FIG. 3B. Similarly, as shown in FIG. 3C, a first thickness 114b of a top portion of a second channel region 102b may be reduced, and a second thickness 114c of a bottom portion of the second channel region 102b may be reduced relative to that of end portions (e.g., end portions of the channel regions 102b) vertically sandwiched between dielectric spacers 110). As described above, these thickness variations may arise due to etching an alloy region 210 that may be generated by performing an annealing operation before the first semiconductor layers 101L are removed.

The presence of the defective interfaces, as shown in FIGS. 3A to 3C may cause detrimental effects on device performance. For example, under operating conditions, electric field distributions may deviate from design specifications. For example, a device design may assume flat interfaces between the gate structure 104 and the stacked channel regions 102 such that electric fields between the gate structure 104 and the stacked channel regions 102 have nominally vertical components and that electric fields between the source/drain layers 108 and the channel regions 102 have nominally horizontal components. However, as shown by the dashed lines in FIG. 3C, the presence of defective interfaces may give rise to an unintended mixture of electric field components, for example, including a horizontal component (see upper and lower dashed arrows) to the electric field between the gate structure 104 and the source/drain epitaxial layers 108. Disclosed embodiments avoid these and other problems (e.g., see FIGS. 2A to 2D) as described in greater detail with reference to FIGS. 4A to 18B, below.

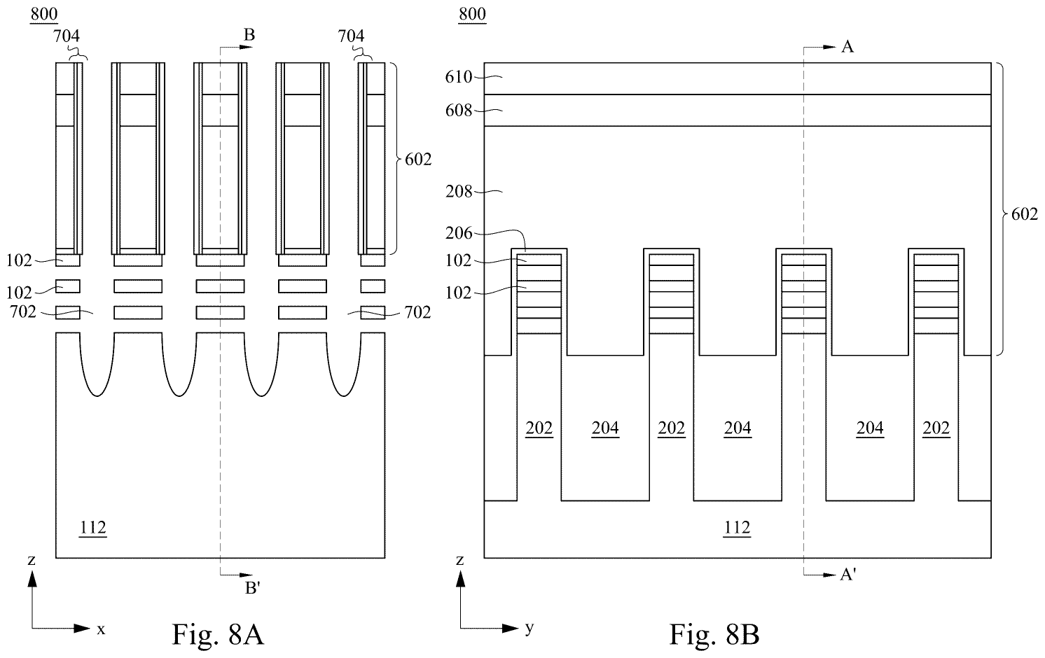

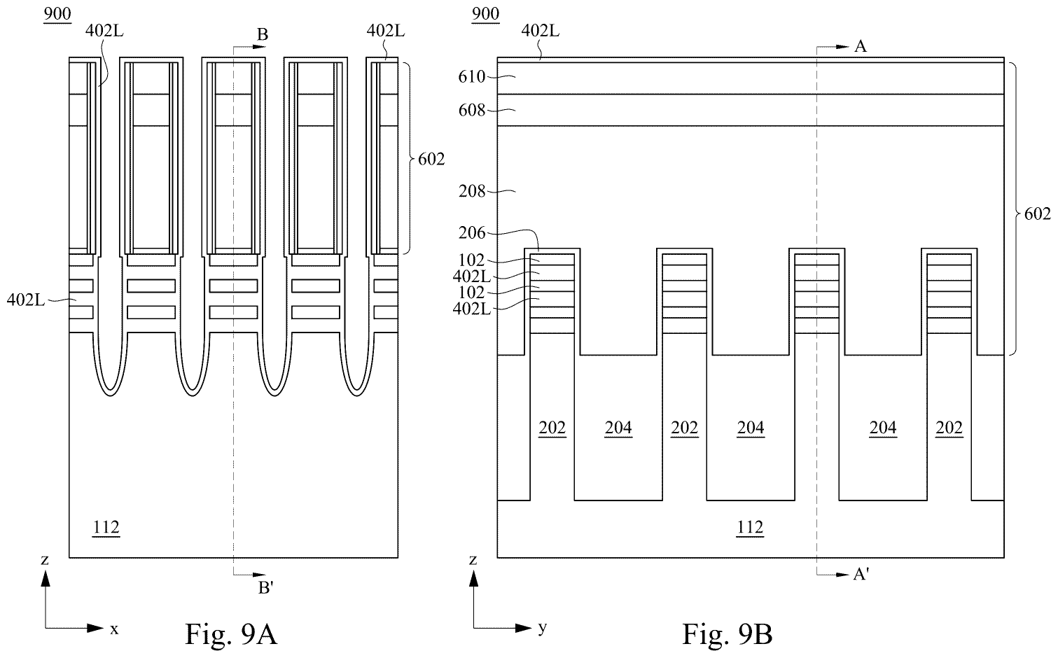

FIG. 4A is a vertical cross-sectional view of an intermediate structure 400a used in the formation of a semiconductor device (100, 400b, 400c, 400d) according to various embodiments. In contrast to the comparative embodiments of FIGS. 2A to 3A, the intermediate structure 400a may be formed by removing the first semiconductor layers 101L before performing any annealing operations. A dielectric interposer layer 402 may then be formed within spaces previously occupied by the first semiconductor layers 101L. The material for the dielectric interposer layer 402 may be chosen to have little or no diffusion or intermixing with the stacked channel regions 102 during subsequent annealing operations. For example, the dielectric interposer layer 402 may be chosen as a dielectric material such as silicon oxide, as described in greater detail in reference to FIGS. 8A to 9B, below.

FIGS. 4B to 4D are vertical cross-sectional views of semiconductor devices (400b, 400c, 400d) formed from the intermediate structure 400a of FIG. 4A according to various embodiments. In this regard, after source/drain layers 108 are formed, one or more annealing operations may be performed to activate dopant species within the source/drain epitaxial layers 108 and in the stacked channel regions 102. During the annealing operations, the dielectric interposer layer 402 prevents the formation of alloy regions 210 in the stacked channel regions 102 that may otherwise be generated in comparative embodiments that lack the dielectric interposer layer 402, as described with reference to FIGS. 2A to 3A, above. As such, a uniform channel thickness 114 of each of the stacked channel regions 102 may be maintained.

Annealing is performed following the formation of doped source/drain epitaxial layers to activate the source/drain epitaxial layers. This process involves heating the wafer to activate dopants, to repair crystal defects, and to achieve precise dopant diffusion profiles. In some embodiment, activation annealing is performed at temperatures ranging from about 800° C. to about 1100° C., depending on the specific dopant and the desired electrical characteristics. (Rapid Thermal Annealing (RTA) is used in some embodiments. In an RTA process, the wafer is exposed to high temperatures (e.g., between about 950° C. and about 1050° C.) for short durations, such as from seconds to minutes. This method allows for rapid dopant activation while minimizing unwanted diffusion. The annealing process is typically carried out at or near atmospheric pressure, though in some applications, low-pressure conditions may be used to reduce the risk of contamination and to exert finer control over material properties. The annealing atmosphere can include inert gases like nitrogen or argon to prevent oxidation, though small amounts of oxygen or hydrogen might be introduced depending on the desired surface chemistry or to repair defects.

Different dopant species require tailored conditions during annealing, according to certain embodiments. For instance, phosphorus and arsenic, which can be used for n-type doping, require higher temperatures (about 950° C. to about 1050° C.) for effective activation, while boron, which can be used for p-type doping, activates at slightly lower temperatures (around 900° C. to 1000° C.). The duration of the annealing process also varies. For example, RTA provides a brief but intense heat exposure, while traditional furnace annealing, used in some embodiments, offers a longer, more gradual heating. Advanced techniques like millisecond annealing or Flash Lamp Annealing can be used for ultra-shallow junctions, where even more precise control over dopant activation and minimal diffusion is required. These methods utilize extremely short pulses of high-intensity light (e.g., laser annealing) to achieve the necessary temperature without extended exposure. In some embodiments, the activation annealing parameters are adjusted to provide sufficient activation of the dopants without causing excessive diffusion, thereby ensuring that the junction profiles remain sharp and the device performance is optimized.

After annealing the intermediate structure 400a, an etching operation may be performed to selectively remove the dielectric interposer layer 402. A gate dielectric layer 106 may then be deposited over exposed surfaces of the stacked channel regions 102 followed by deposition of a conductive material to form the gate structure 104. As shown in FIGS. 4B to 4D, the dielectric spacers (110b, 110c, 110d) may have various lateral geometric profiles. For example, as shown in FIG. 4B, the dielectric spacer 110b has a convex interface with the gate structure 104 while, as shown in FIG. 4C, the dielectric spacer 110c has a concave interface with the gate structure 104.

Whether the interface is concave or convex may depend on the order in which various manufacturing operations are performed. For example, the convex interface of the dielectric spacers 110a of FIG. 4B may be formed by partially etching the dielectric interposer layer 402 before the formation of the dielectric spacers 110a. Alternatively, the concave interfaces of the dielectric spacers 110c of FIG. 4C may be formed by partially etching the dielectric spacers 110c after removal of the dielectric interposer layer 402. In still further embodiments, the order and timing of various manufacturing processes may be tuned such that the interface between the dielectric spacers 110d and the gate structure 104 assumes an essentially flat profile, as shown in FIG. 4D.

As shown in each of FIGS. 4B to 4D a high degree of channel thickness 114 uniformity is achieved through the use of dielectric interposer layer 402, as described in greater detail with reference to FIGS. 5A to 18B, below. In this regard, each of the stacked channel regions 102 has a channel thickness 114 that ranges from about 5 nm to about 10 nm and a thickness variation that is less than about 1 nm. As shown in each of FIGS. 4B to 4D a high degree of channel thickness 114 uniformity is achieved through the use of dielectric interposer layer 402, as described in greater detail with reference to FIGS. 5A to 18B, below. In this regard, each of the stacked channel regions 102 has a channel thickness 114 that is sufficiently thick (e.g., 5 nm for silicon) to reduce surface scattering while keeping the device size as small as possible (e.g., a channel thickness 114 that is less than 10 nm for silicon). In other embodiments, different channel materials are used having different respective ranges of channel thickness 114.

The use of the dielectric interposer 402 also leads to thickness variation that is less than 1 nm when silicon is used to form the channel region 102. The small value of thickness variation (i.e., less than 1 nm) corresponds to a low degree of intermixing between the first semiconductor layers 101L and the second semiconductor layers 102L that is achieved by removing the first semiconductor layer 101L before performing an annealing operation. Other values of the thickness variation (i.e., greater than or less than 1 nm) occur when other materials are used to form the channel region 102 in other embodiments.

The high degree of thickness uniformity leads to improved device performance including increased source/drain current and reduced ohmic loss relative to comparative embodiments that have reduced-quality interfaces. The detailed shape of the interface between the dielectric spacers (110b, 110c, 110d) and the gate structure 104 is less important than the flat shape of the interfaces between the stacked channel regions 102 and adjacent portions of the gate structure 104 in some embodiments. In this regard, the dielectric spacers (110b, 110c, 110d) need only be sufficiently thick to prevent electrical conduction between the gate structure 104 and the source/drain epitaxial layers 108. According to embodiments, a detailed process flow, that is used to generate the respective semiconductor devices (100, 400b, 400c, 400d) of FIGS. 1, 4B, 4C, and 4D, is described with reference to FIGS. 5A to 18B, below.

FIG. 5A is a vertical cross-sectional view of an intermediate structure 500 used to form a semiconductor device (100, 400b, 400c, 400d), and FIG. 5B is a further vertical cross-sectional view of the intermediate structure of FIG. 5A according to various embodiments. The vertical plane that defines the cross-sectional view of FIG. 5A is indicated by the cross-section A-A′ in FIG. 5B, and similarly, the vertical plane that defines the cross-sectional view of FIG. 5B is indicated by the cross-section B-B′ in FIG. 5A. The intermediate structure 500 is generated by forming an alternating layer stack 501 including first semiconductor layers 101L and second semiconductor layers stacked 102L along a first direction (i.e., the z-direction) that is perpendicular to interfaces of the alternating layer stack 501. The alternating layer stack 501 is then patterned to form a plurality of fin structures 202.

As shown in FIGS. 5A and 5B, the fin structures 202 have a height 502 extending along the first direction (i.e., the z-direction), a length 504 along a second direction (i.e., the x-direction) that is perpendicular to the first direction, and a width 506 along a third direction (i.e., the y-direction) that is perpendicular to the first direction and the second direction. As shown in FIG. 5B, the fin structures 202 may be partially surrounded by a shallow trench isolation structure 204. According to various embodiments, the first semiconductor layers 101L, and the second semiconductor layers 102L are made of materials having different lattice constants, and may include one or more layers of Si, Ge, SiGe, GaAs, InSb, GaP, GaSb, InAlAs, InGaAs, GaSbP, GaAsSb or InP.

In some embodiments, the first semiconductor layers 101L and the second semiconductor layers 102L are made of Si, a Si compound, SiGe, Ge, or a Ge compound. In some embodiments, the first semiconductor layers 101L are Si₁₋ₓGeₓ, where x is equal to or more than about 0.1 and equal to or less than about 0.6, and the second semiconductor layers 102L are Si or Si_{1-y}Ge_{y}, where y is smaller than x and equal to or less than about 0.2. In this disclosure, an “M” compound” or an “M-based compound” means the majority of the compound is M. In other embodiments, the second semiconductor layers 102L are Si₁₋ₓGeₓ, where x is equal to or more than about 0.1 and equal to or less than about 0.6, and the first semiconductor layers 101L are Si or Si_{1-y}Ge_{y}, where y is smaller than x and equal to or less than about 0.2.

The first semiconductor layers 101L and the second semiconductor layers 102L are epitaxially formed over the semiconductor substrate 112. In general, the thickness of the first semiconductor layers 101L may be equal to or than that of the second semiconductor layers 102L, and is between 35 nm and 60 nm in some embodiments, and is between 10 nm and 30 nm in other embodiments. (In general, 102L (channel material) will be equal or thicker than 101L (interposer) in the beginning of the processes. The thickness of the channel material will be reduced during the following processes, such as sheet release. For the embodiments in TSMC, the thickness of 102L (channel material) may be equal or larger than the thickness of 104 (metal gate) in the final product. )The thickness of the second semiconductor layers 102L is between 5 nm and 60 nm in some embodiments and is between 10 nm and 30 nm in other embodiments.

The thickness of the first semiconductor layers 101L may be the same as, or different from the thickness of the second semiconductor layers 102L. Although three first semiconductor layers 101L and three second semiconductor layers 102L are shown in FIGS. 5A and 5B, the numbers are not limited to three and can be one, two, or more than four, and less than twenty. In some embodiments, the number of the first semiconductor layers 101L is greater by one than the number of the second semiconductor layers 102L (i.e., the top layer is the first semiconductor layer 101L).

The fin structures 202 may be patterned by any suitable method. For example, the fin structures 202 may be patterned using one or more photolithography processes, including double-patterning or multi-patterning processes. Generally, double-patterning, or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fin structures.

The number of the fin structures 202 is not limited to four as shown in FIG. 5B, and may be as small as a single fin structure 202. In some embodiments, one or more dummy fin structures (not shown) are formed on both sides of the fin structures 202 to improve pattern fidelity in the patterning operations. As shown in FIG. 5B, the fin structures 202 have upper portions constituted by the stacked semiconductor layers (101L, 102L) and well portions (i.e., portions surrounded by the shallow trench isolation structure 204. The width 506 of the fin structure 202 is between 10 nm and 40 nm in some embodiments and is between 20 nm and 30 nm in other embodiments.

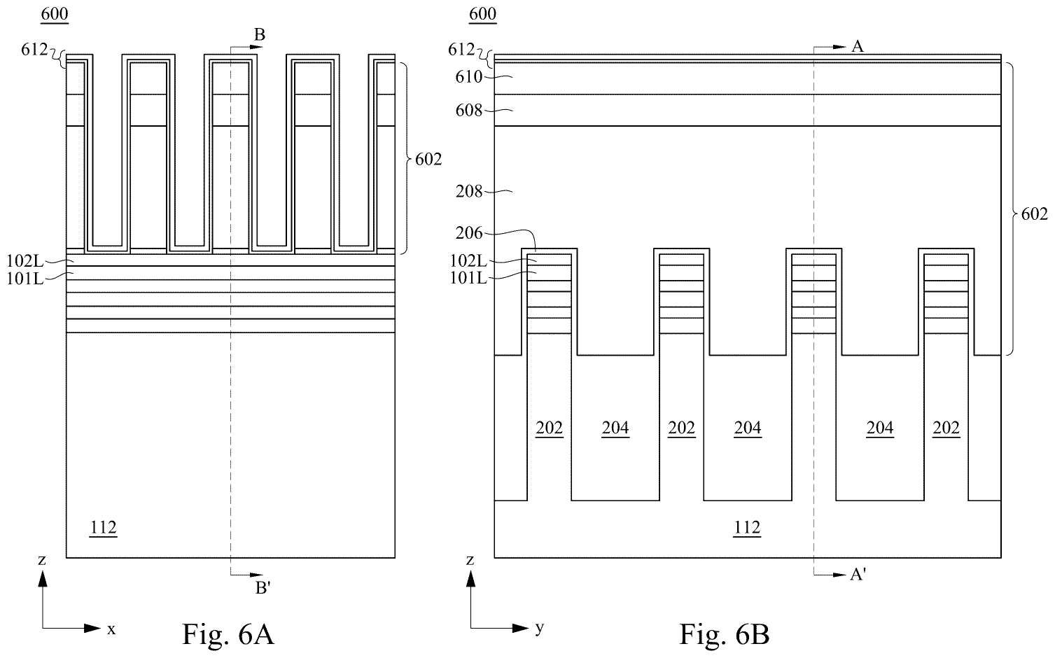

After patterning the alternating layer stack 501, an insulating material may be deposited over the fin structures 202. The insulating material may include silicon oxide, silicon nitride, silicon oxynitride (SiON), SiOCN, SiCN, fluorine-doped silicate glass (FSG), or a low-k dielectric material, formed by LPCVD (low-pressure chemical vapor deposition), plasma-enhanced CVD (PECVD) or flowable CVD. Then, a planarization operation, such as a chemical mechanical planarization (CMP) method and/or an etch-back method, is performed to form the shallow trench isolation structure 204. After the shallow trench isolation structure 204 is formed, a sacrificial gate structure 602 is formed, as shown in FIGS. 6A and 6B. For approaches using oxide interposer, SiN hard mask be deposited on the top of STI. The hard mask material on the sidewall may be removed using any suitable etch process, such as a dry etch or wet etch.

FIG. 6A is a vertical cross-sectional view of a further intermediate structure 600 used to form a semiconductor device (100, 400b, 400c, 400d), and FIG. 6B is a further vertical cross-sectional view of the intermediate structure of FIG. 6A according to various embodiments. The vertical plane that defines the cross-sectional view of FIG. 6A is indicated by the cross-section A-A′ in FIG. 6B, and similarly, the vertical plane that defines the cross-sectional view of FIG. 6B is indicated by the cross-section B-B′ in FIG. 6A. The sacrificial gate structure 602 is formed over portions of the fin structures 202 which are to be channel regions. The sacrificial gate structure 602 defines the channel region of the GAA-FET.

The sacrificial gate structure 602 includes a sacrificial gate dielectric layer 206 and a sacrificial gate electrode layer 208. The sacrificial gate dielectric layer 206 includes one or more layers of insulating material, such as a silicon oxide-based material. In one embodiment, silicon oxide formed by CVD is used. The thickness of the sacrificial gate dielectric layer 206 is between 1 nm and 5 nm in some embodiments. The sacrificial gate structure 602 is formed by initially blanket depositing the sacrificial gate dielectric layer 206 over the fin structures 202. A sacrificial gate electrode layer 208 is then blanket deposited on the sacrificial gate dielectric layer 206 and over the fin structures 202, such that the fin structures 202 are fully embedded in the sacrificial gate electrode layer 208.

The sacrificial gate electrode layer 208 includes silicon such as polycrystalline silicon or amorphous silicon. The thickness of the sacrificial gate electrode layer 208 is between 100 nm and 200 nm in some embodiments. In some embodiments, the sacrificial gate electrode layer 208 is subjected to a planarization operation. The sacrificial gate dielectric layer 206 and the sacrificial gate electrode layer 208 are deposited using chemical vapor deposition CVD, including low-pressure chemical vapor deposition (LPCVD) and plasma-enhanced chemical vapor deposition (PECVD), physical vapor deposition (PVD), atomic layer deposition (ALD), or other suitable process. Subsequently, a mask layer (608, 610) is formed over the sacrificial gate electrode layer 208. The mask layer (608, 610) includes a pad silicon nitride layer 608 and a silicon oxide mask layer 610 in some embodiments.

Next, a patterning operation is performed on the mask layer (608, 610) and the sacrificial gate electrode layer 208 is patterned into the sacrificial gate structure 602, as shown in FIGS. 6A and 6B. The sacrificial gate structure 602 includes the sacrificial gate dielectric layer 206, the sacrificial gate electrode layer 208 (e.g., polysilicon), the pad silicon nitride layer 608, and the silicon oxide mask layer 610. A cover layer 612 for sidewall spacers is next formed over the sacrificial gate structure 602, as shown in FIGS. 6A and 6B. The cover layer 612 is deposited conformally so that it has substantially equal thicknesses on vertical surfaces, such as the sidewalls, horizontal surfaces, and the top of the sacrificial gate structure. In some embodiments, the cover layer 612 has a thickness between 5 nm and 20 nm. The cover layer 612 includes one or more of silicon nitride, SiON, SiCN, SiCO, SiOCN, or any other suitable dielectric material. The cover layer 612 is formed by ALD or CVD, or any other suitable method. In this embodiment, the cover layer 612 includes two layers but in other embodiments, it includes a single layer or three or more layers.

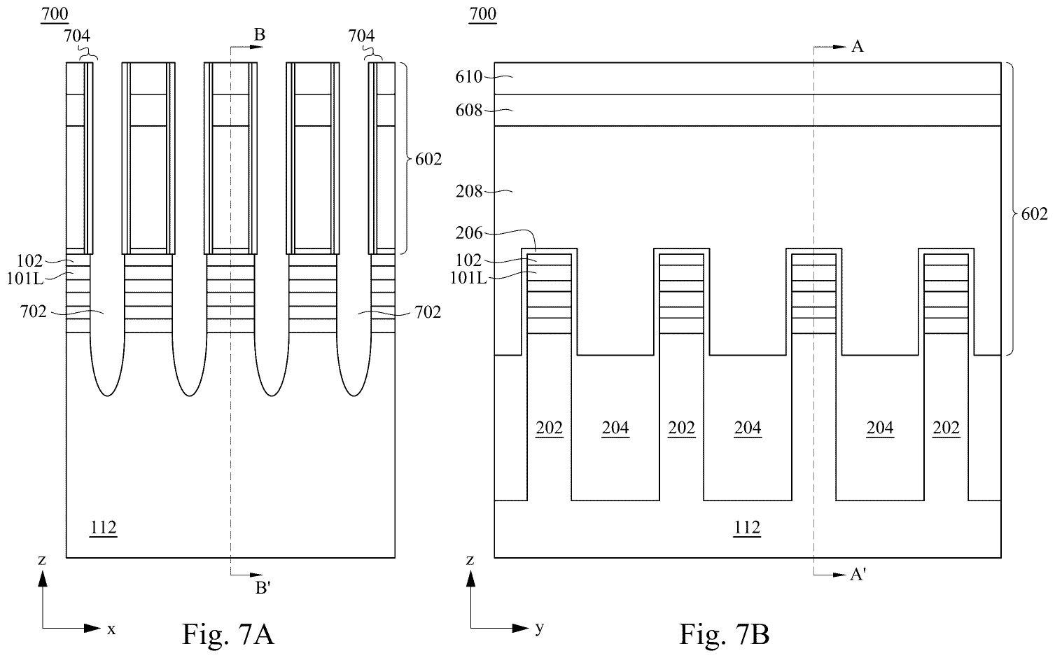

FIG. 7A is a vertical cross-sectional view of a further intermediate structure 700 used to form a semiconductor device (100, 400b, 400c, 400d), and FIG. 7B is a further vertical cross-sectional view of the intermediate structure of FIG. 7A according to various embodiments. The vertical plane that defines the cross-sectional view of FIG. 7A is indicated by the cross-section A-A′ in FIG. 7B, and similarly, the vertical plane that defines the cross-sectional view of FIG. 7B is indicated by the cross-section B-B′ in FIG. 7A. The intermediate structure 700 is formed by patterning the intermediate structure 600 to form source/drain regions 702 in each of the fin structures 202. In this regard, the sacrificial gate structure 602 serves as a mask when patterning the source/drain regions 702. As shown in FIGS. 7A and 7B, horizontal portions of the cover layer 612 are removed by the patterning operation that generates the source/drain regions 702. Remaining portions of the cover layer 612 form sidewall spacers 704 on side surfaces of the sacrificial gate structure 602.

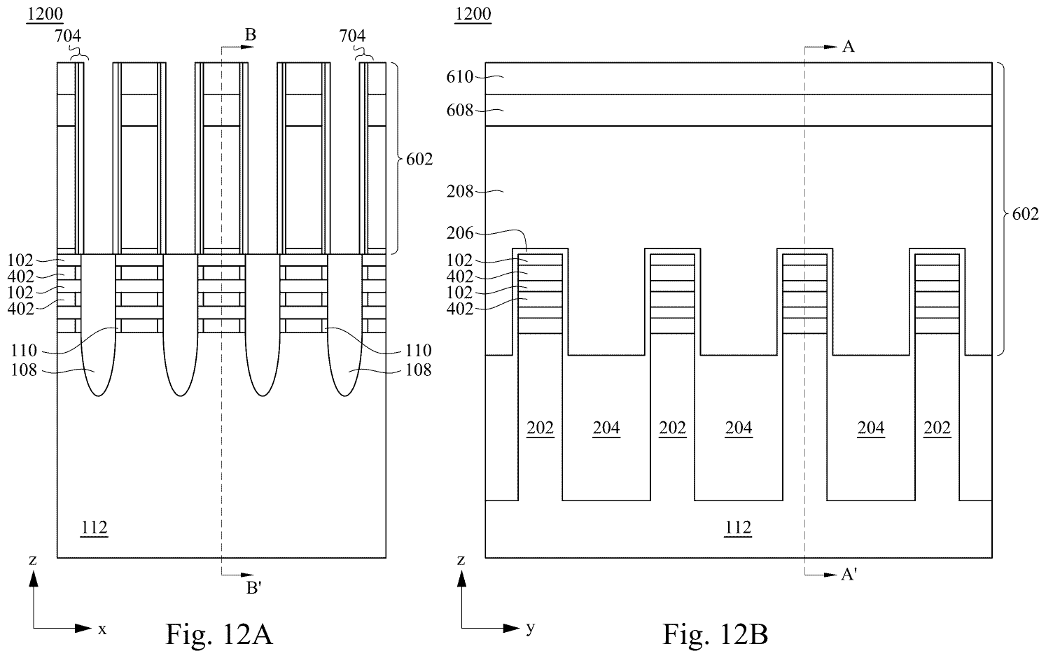

By patterning the intermediate structure 600 to form the source/drain regions 702, the stacked layers of the first semiconductor layers 101L and the second semiconductor layers 102L are partially exposed on opposite sides of the sacrificial gate structure 602 along the second direction (i.e., the x-direction). In further processing operations (e.g., see FIGS. 12A and 12B) the exposed ends of second semiconductor layers 102L are connected to source/drain epitaxial layers 108. As such, the portions of the second semiconductor layers 102L that remain after patterning the intermediate structure 600 become the stacked channel regions 102 described above with reference to FIGS. 1, 4B, 4C, and 4D.

In this disclosure, a source and a drain are interchangeably used and the structures thereof are substantially the same. In FIGS. 7A and 7B, five sacrificial gate structures 602 are formed over four fin structures 202, but the number of sacrificial gate structures 602 is not limited to five and the number of fin structures 202 is not limited to four. In other embodiments, the number of fin structures 202 and sacrificial gate structures 602 may be as few as one each or may be greater than the numbers shown in FIGS. 7A and 7B. In certain embodiments, one or more dummy sacrificial gate structures (not shown) are formed on opposite sides of the intermediate structure 700 to improve pattern fidelity.

FIG. 8A is a vertical cross-sectional view of a further intermediate structure 800 that may be used to form a semiconductor device (100, 400b, 400c, 400d), and FIG. 8B is a further vertical cross-sectional view of the intermediate structure of FIG. 8A, according to various embodiments. The vertical plane that defines the cross-sectional view of FIG. 8A is indicated by the cross-section A-A′ in FIG. 8B, and similarly, the vertical plane that defines the cross-sectional view of FIG. 8B is indicated by the cross-section B-B′ in FIG. 8A. The intermediate structure 800 is formed from the intermediate structure 700 by performing an etching operation to remove the first semiconductor layers 101L.

By removing the first semiconductor layers 101L, the channel regions 102 are formed as wires or sheets from the second semiconductor layers 102L, as shown in FIGS. 8A and 8B. The first semiconductor layers 101L can be removed or etched using an etchant that can selectively etch the first semiconductor layers 101L relative to the second semiconductor layers 102L. Various etching processes may be performed depending on the materials used for the first semiconductor layers 101L and the second semiconductor layers 102L. When the first semiconductor layers 101L are SiGe and the second semiconductor layers 102L are Si, the first semiconductor layers 101L may be selectively etched by using a wet etchant such as, but not limited to, a mixed solution of H₂O₂, CH₃COOH, and HF, followed by H₂O cleaning. In some embodiments, the etching by the mixed solution and cleaning with water is repeated 10 to 25 times. The etching time by the mixed solution is between 1 min and 2 min in some embodiments. The mixed solution is used at a temperature between 60° C. and 90° C. in some embodiments. In some embodiments, other etchants are used.

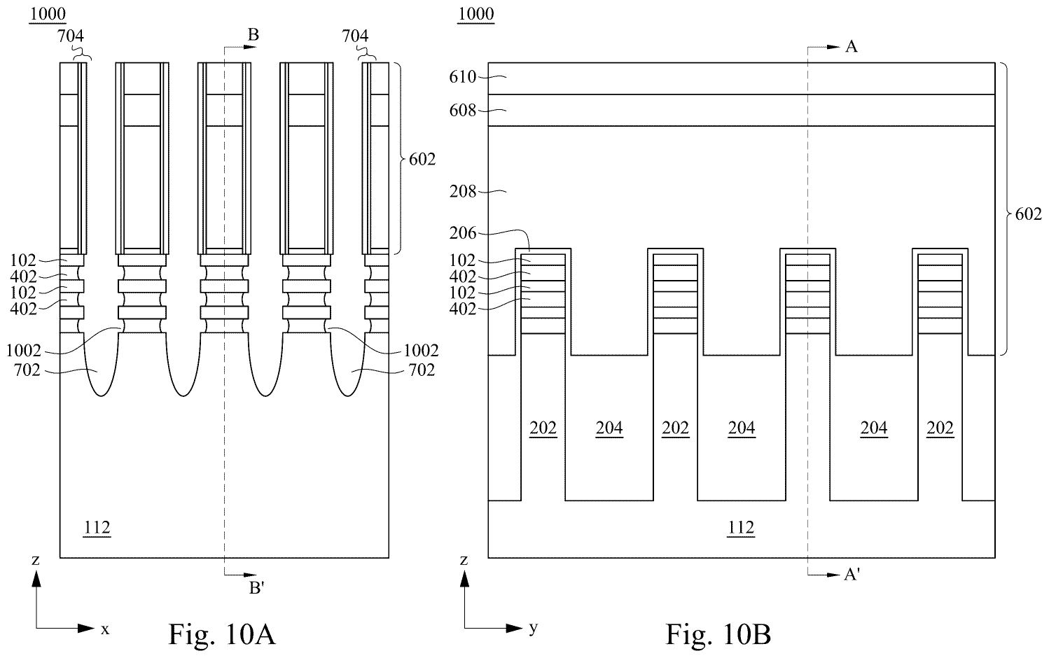

FIG. 9A is a vertical cross-sectional view of a further intermediate structure 900 used to form a semiconductor device (100, 400b, 400c, 400d), and FIG. 9B is a further vertical cross-sectional view of the intermediate structure of FIG. 9A according to various embodiments. The vertical plane that defines the cross-sectional view of FIG. 9A is indicated by the cross-section A-A′ in FIG. 9B, and similarly, the vertical plane that defines the cross-sectional view of FIG. 9B is indicated by the cross-section B-B′ in FIG. 9A. The intermediate structure 900 is formed from the intermediate structure 800 by depositing a dielectric material 402L over the intermediate structure 800 to thereby fill spaces between the stacked channel regions 102. As such, the dielectric interposer layer 402, described above with reference to FIG. 4A is formed. According to various embodiments, the dielectric material 402L may be one of silicon oxide, SiON, SiOC, SiCN, and SiOCN, or any other suitable dielectric material. The dielectric material 402L may then be etched to form the dielectric interposer layers 402, as described in greater detail with reference to FIGS. 10A and 10B, below.

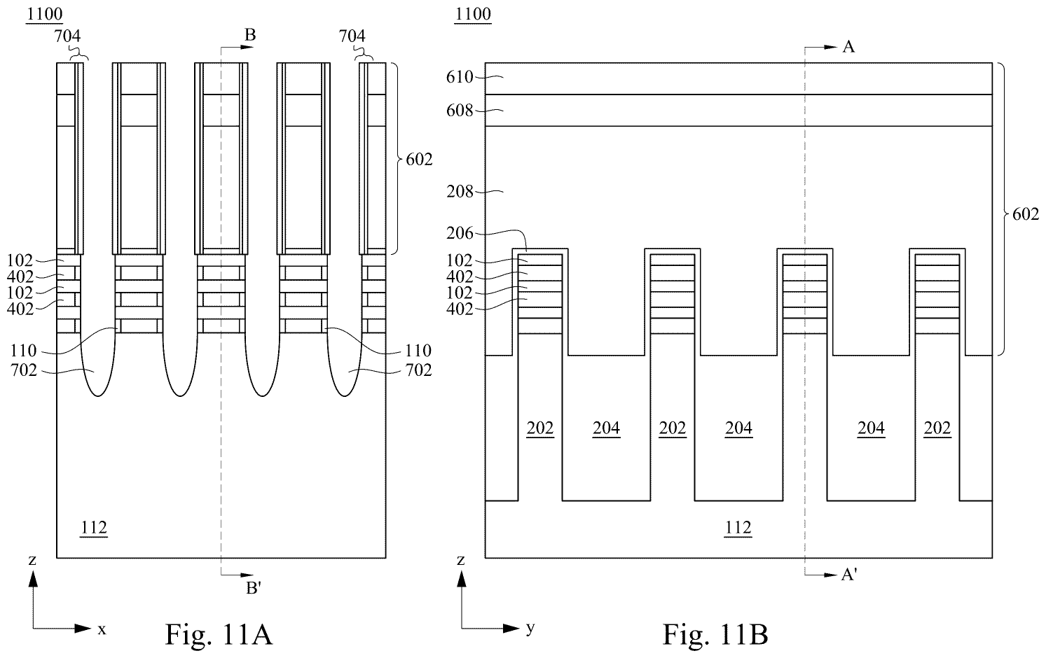

FIG. 10A is a vertical cross-sectional view of a further intermediate structure 1000 used to form a semiconductor device (100, 400b, 400c, 400d), and FIG. 10B is a further vertical cross-sectional view of the intermediate structure of FIG. 10A according to various embodiments. The vertical plane that defines the cross-sectional view of FIG. 10A is indicated by the cross-section A-A′ in FIG. 10B, and similarly, the vertical plane that defines the cross-sectional view of FIG. 10B is indicated by the cross-section B-B′ in FIG. 10A. The intermediate structure 1000 is formed from the intermediate structure 900 by performing an etching process to remove excess portions of the dielectric material 402L and trim edges of the dielectric interposer layers 402. Various etching processes may be used. For example, if the dielectric material 402L is silicon oxide, a wet etching process using hydrogen fluoride may be performed. Alternatively, a dry etching process using reactive ion etching plasmas such as CF₄ or CHF₃ may be used. As shown in FIG. 10A, the etching process may be allowed to progress such that cavities 1002 are formed on opposite ends of the dielectric interposer layers 402. The cavities 1002 may then be filled with a dielectric material to thereby form the dielectric spacers 110 (e.g., see FIGS. 1 and 4A to 4D), as described in greater detail with reference to FIGS. 11A and 11B, below.

FIG. 11A is a vertical cross-sectional view of a further intermediate structure 1100 used to form a semiconductor device (100, 400b, 400c, 400d), and FIG. 11B is a further vertical cross-sectional view of the intermediate structure of FIG. 11A according to various embodiments. The vertical plane that defines the cross-sectional view of FIG. 11A is indicated by the cross-section A-A′ in FIG. 11B, and similarly, the vertical plane that defines the cross-sectional view of FIG. 11B is indicated by the cross-section B-B′ in FIG. 11A. The intermediate structure 1100 is formed from the intermediate structure 1000 by forming dielectric spacers 110.

The dielectric spacers 110 may be formed by conformally depositing an insulating layer (not shown) followed by performing an etching process to remove excess portions of the insulating layer. As such, the insulating layer may be formed on the etched lateral ends of the dielectric interposer layers 402 and end faces of the stacked channel regions 102. The insulating layer includes one of silicon nitride and silicon oxide, SiON, SiOC, SiCN, and SiOCN, or any other suitable dielectric material. The insulating layer is made of a different material than the sidewall spacers 704. The insulating layer has a thickness between 1.0 nm and 10.0 nm in some embodiments. In other embodiments, the insulating layer has a thickness between 2.0 nm and 5.0 nm. The insulating layer can be formed by ALD or any other suitable method. By conformally forming the insulating layer, the cavities 1002 are filled with the insulating layer.

After the insulating layer is formed, an etching operation is performed to partially remove the insulating layer, thereby forming dielectric spacers 110, as shown in FIG. 11A. In some embodiments, the end face of the dielectric spacers 110 is recessed more than the end face of the channel regions 102. The recessed amount is between 0.2 nm and 3 nm in some embodiments and is between 0.5 nm and 2 nm in other embodiments. In other embodiments, the recessed amount is less than 0.5 nm and may be equal to zero (i.e., the end face of the dielectric spacer 110 and the end face of the channel regions 102 are flush with one another). In some embodiments, before forming the insulating layer, an additional insulating layer having a smaller thickness than the insulating layer is formed, and thus the dielectric spacers 110 have a two-layer structure. In some embodiments, the dielectric spacers 110 may have non-uniform widths.

FIG. 12A is a vertical cross-sectional view of a further intermediate structure 1200 used to form a semiconductor device (100, 400b, 400c, 400d), and FIG. 12B is a further vertical cross-sectional view of the intermediate structure of FIG. 12A according to various embodiments. The vertical plane that defines the cross-sectional view of FIG. 12A is indicated by the cross-section A-A′ in FIG. 12B, and similarly, the vertical plane that defines the cross-sectional view of FIG. 12B is indicated by the cross-section B-B′ in FIG. 12A. The intermediate structure 1200 is formed from the intermediate structure 1100 by forming source/drain epitaxial layers 108 in the source/drain regions 702. The specific composition of the source/drain epitaxial layer 108 is chosen based on the type of device (e.g., n-type or p-type) that is being formed, as follows.

Before the source/drain epitaxial layers 108 are formed, a pre-clean operation is performed to remove an oxide layer formed on the surface of the source/drain regions 702. In some embodiments, the pre-clean operation includes a plasma treatment using Ar and/or NH₃ plasma. The process temperature is between room temperature and 300° C. in some embodiments. Then, a chemical cleaning operation is performed using an HCl gas to remove residual gases from a vacuum chamber, which would otherwise cause defects. The process temperature of the chemical cleaning is higher than the pre-clean temperature and is between 400° C. and 700° C. in some embodiments, and is between 500° C. and 600° C. in other embodiments.

After the chemical cleaning, the epitaxial layer is made of SiP or SiAs for the source/drain epitaxial layer 108 for an n-type FET and is made of SiGe doped with B for the source/drain epitaxial layer 108 for a p-type FET. In some embodiments, for a p-type FET, the channel regions 102 are made of Si₁₋ₓGeₓ, where x is equal to or more than about 0.2 and equal to or less than about 0.3. The Ge content in the first epitaxial layer for a p-type FET is the same as the Ge content of the channel regions 102 or the difference in the Ge content is about 0.01 to 0.03 in some embodiments. The source/drain epitaxial layers 108 may be formed by various deposition techniques such as molecular beam epitaxy (MBE), CVD, or ALD. In some embodiments, isolation layer formed on the bottom of source or drain cavity will be adopted to avoid leakage current through source-well-drain path. The isolation layer may by formed by depositing a suitable dielectric film, such as SiO, SiN, or SiON (cloud be single or multi-films) on the structure, then removing the material on the side wall by a wet or dry etch processes. In some embodiments, a dielectric liner, such as SiO, SiN, SiCNO, SiC, SiNO, or SiCN will be deposited on the surface of the source and drain structures to avoid any damage in the following processes (not plotted in the figures).

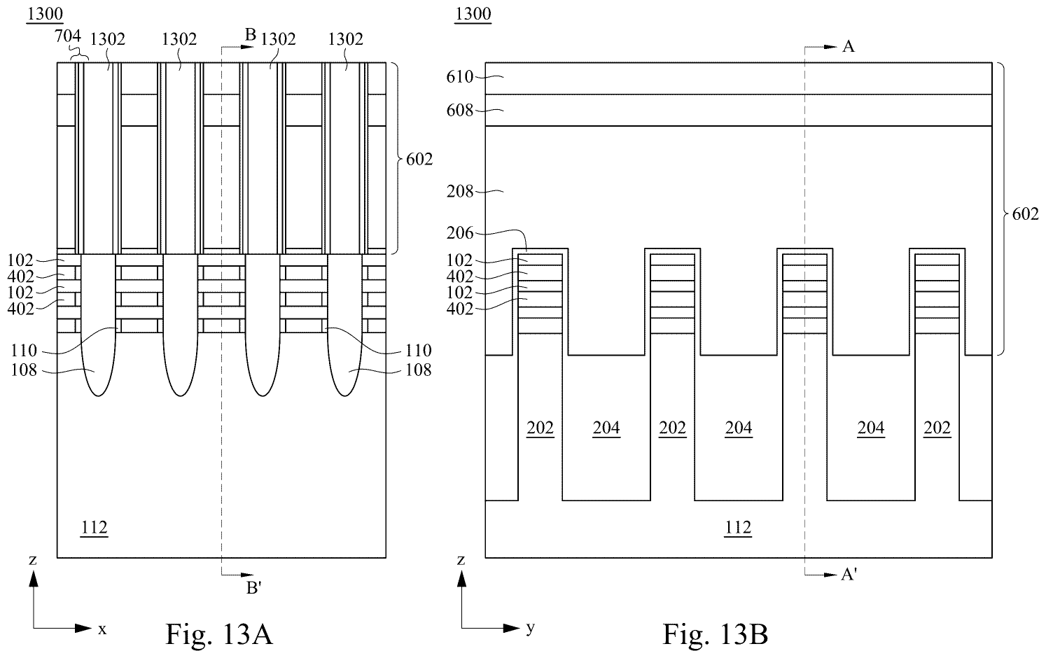

FIG. 13A is a vertical cross-sectional view of a further intermediate structure 1300 used to form a semiconductor device (100, 400b, 400c, 400d), and FIG. 13B is a further vertical cross-sectional view of the intermediate structure of FIG. 13A, according to various embodiments. The vertical plane that defines the cross-sectional view of FIG. 13A is indicated by the cross-section A-A′ in FIG. 13B, and similarly, the vertical plane that defines the cross-sectional view of FIG. 13B is indicated by the cross-section B-B′ in FIG. 13A. The intermediate structure 1300 is formed by depositing an interlayer dielectric layer 1302 over the intermediate structure 1200. The materials for the interlayer dielectric layer 1302 include compounds of one or more of Si, O, C, and H, such as silicon oxide, SiCOH, and SiOC. Organic materials, such as polymers, may also be used for the interlayer dielectric layer 1302. After the interlayer dielectric layer 1302 is formed, a planarization operation, such as CMP, is performed, so that the top portion of the sacrificial gate electrode layer 208 is exposed, as shown in FIGS. 13A and 13B.

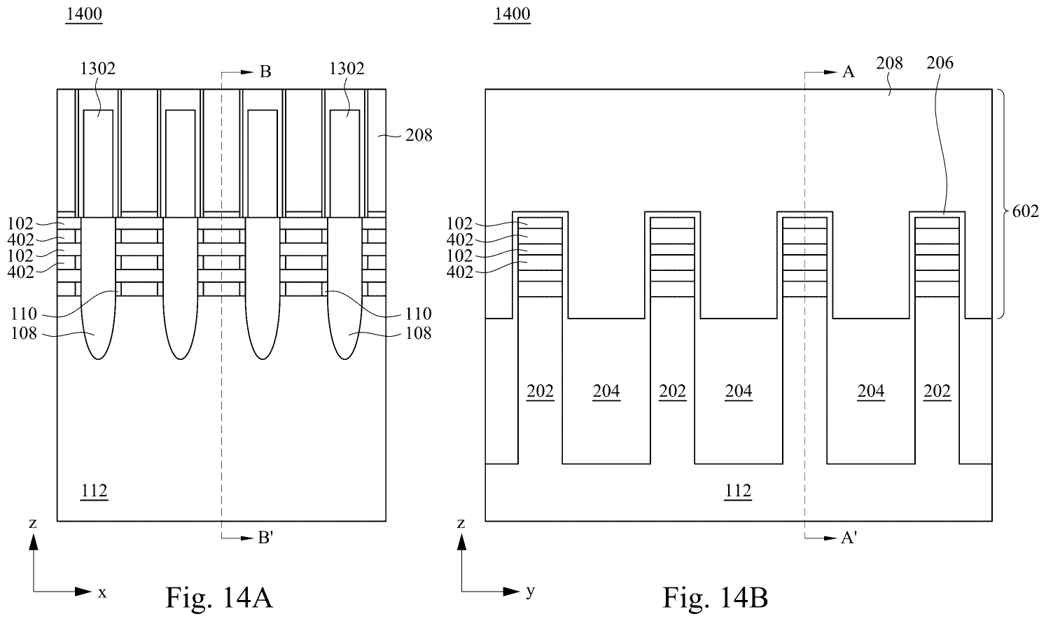

In some embodiments, a dielectric capping layer, comprising silicon nitride, silicon oxynitride, or the like, will be used on top of ILD to avoid ILD damage during sheet release processes. The capping layer may be formed by any suitable etch processes, such as a dry etch or a wet etch, then depositing dielectric material on the structures. FIG. 14A is a vertical cross-sectional view of a further intermediate structure 1400 used to form a semiconductor device (100, 400b, 400c, 400d), and FIG. 14B is a further vertical cross-sectional view of the intermediate structure of FIG. 14A according to various embodiments. The vertical plane that defines the cross-sectional view of FIG. 14A is indicated by the cross-section A-A′ in FIG. 14B, and similarly, the vertical plane that defines the cross-sectional view of FIG. 14B is indicated by the cross-section B-B′ in FIG. 14A. The intermediate structure 1400 is formed from the intermediate structure 1300 by performing an additional planarization process (e.g., such as CMP) to remove the pad silicon nitride layer 608, and the silicon oxide mask layer 610, and capping layer.

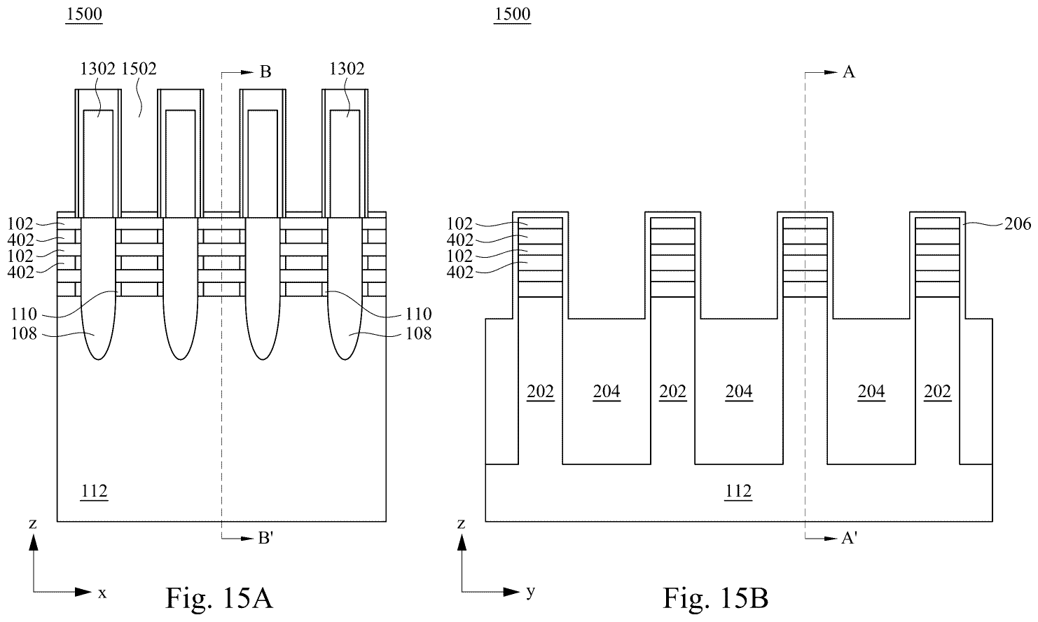

FIG. 15A is a vertical cross-sectional view of a further intermediate structure 1500 used to form a semiconductor device (100, 400b, 400c, 400d), and FIG. 15B is a further vertical cross-sectional view of the intermediate structure of FIG. 15A, according to various embodiments. The vertical plane that defines the cross-sectional view of FIG. 15A is indicated by the cross-section A-A′ in FIG. 15B, and similarly, the vertical plane that defines the cross-sectional view of FIG. 15B is indicated by the cross-section B-B′ in FIG. 15A. The intermediate structure 1500 is formed from the intermediate structure 1400 by removing the sacrificial gate electrode layer 208 to generate gate openings 1502 over the stacked channel regions 102.

The interlayer dielectric layer 1302 protects the source/drain epitaxial layers 108 during the removal of the sacrificial gate electrode layer 208. The sacrificial gate electrode layer 208 may be removed using plasma dry etching and/or wet etching. When the sacrificial gate electrode layer 208 is polysilicon and the interlayer dielectric layer 1302 is silicon oxide, a wet etchant such as a tetramethylammonium hydroxide (TMAH) solution may be used to selectively remove the sacrificial gate electrode layer 208.

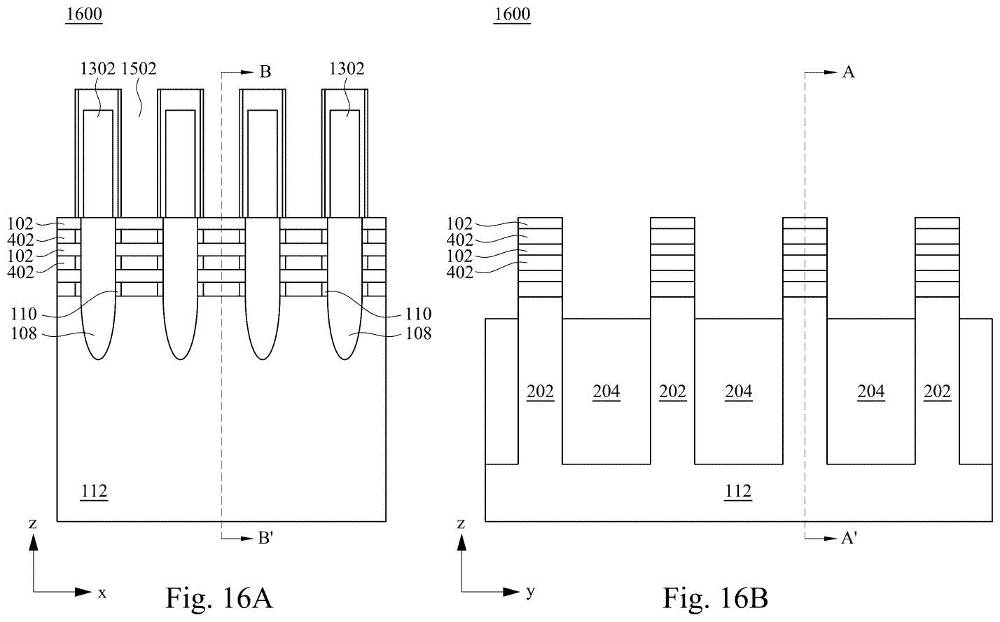

FIG. 16A is a vertical cross-sectional view of a further intermediate structure 1600 used to form a semiconductor device (100, 400b, 400c, 400d), and FIG. 16B is a further vertical cross-sectional view of the intermediate structure of FIG. 16A according to various embodiments. The vertical plane that defines the cross-sectional view of FIG. 16A is indicated by the cross-section A-A′ in FIG. 16B, and similarly, the vertical plane that defines the cross-sectional view of FIG. 16B is indicated by the cross-section B-B′ in FIG. 16A. The intermediate structure 1600 is formed from the intermediate structure 1500 by removing the sacrificial gate dielectric layer 206, which may be removed using plasma dry etching and/or wet etching.

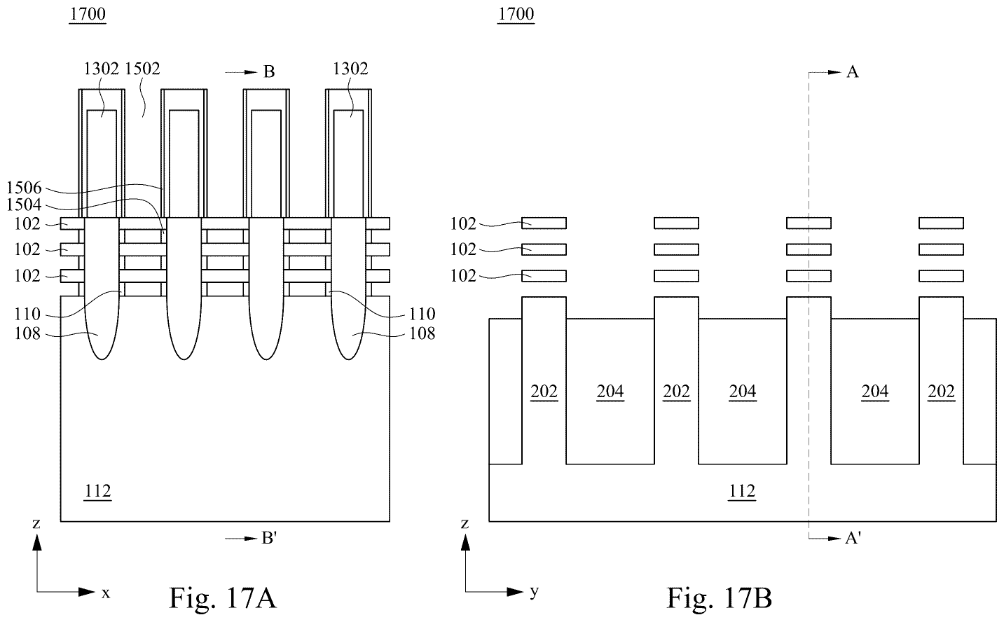

FIG. 17A is a vertical cross-sectional view of a further intermediate structure 1700 used to form a semiconductor device (100, 400b, 400c, 400d), and FIG. 17B is a further vertical cross-sectional view of the intermediate structure of FIG. 17A according to various embodiments. The vertical plane that defines the cross-sectional view of FIG. 17A is indicated by the cross-section A-A′ in FIG. 17B, and similarly, the vertical plane that defines the cross-sectional view of FIG. 17B is indicated by the cross-section B-B′ in FIG. 17A. The intermediate structure 1700 is formed from the intermediate structure 1600 by removing dielectric interposer layers 402 by performing an etching process that is selective to the stacked channel regions 102. Various etching processes may be used. For example, if the dielectric interposer layer 402 is silicon oxide, a wet etching process using hydrogen fluoride may be performed. Alternatively, a dry etching process using reactive ion etching plasmas or gas phase chemicals, such as CF₄, CHF₃, HF/NH₃ may be used. During the etching process, the dielectric spacers 110 act as etch-stop layers for the removal of the dielectric interposer layer 402. Further, as shown in FIG. 17A, first inner edges 1504 of the dielectric spacers 110 are aligned with second inner edges of the gate openings 1502.

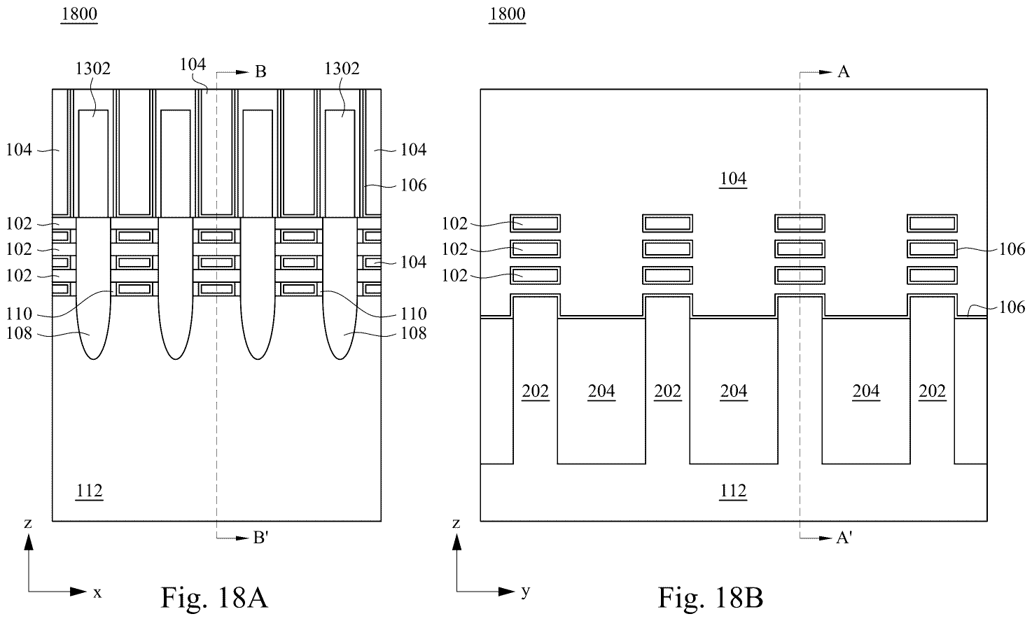

FIG. 18A is a vertical cross-sectional view of a further intermediate structure 1800 used to form a semiconductor device (100, 400b, 400c, 400d), and FIG. 18B is a further vertical cross-sectional view of the intermediate structure of FIG. 18A according to various embodiments. The vertical plane that defines the cross-sectional view of FIG. 18A is indicated by the cross-section A-A′ in FIG. 18B, and similarly, the vertical plane that defines the cross-sectional view of FIG. 18B is indicated by the cross-section B-B′ in FIG. 18A. The intermediate structure 1800 is formed from the intermediate structure 1700 by depositing a gate dielectric layer 106 over the intermediate structure 1700 followed by deposition of a conductive material to thereby form the gate structure 104. In this regard, the conductive material is deposited in gate openings 1502 such that the resulting gate structure 104 surrounds each of the stacked channel regions 102 and is separated from the stacked channel regions 102 by the gate dielectric layer 106, as described above with reference to FIGS. 1 and 4B to 4D.

As shown in FIGS. 18A and 18B, the gate dielectric 106 and the conductive material forming portions of the gate structure 104 are formed in spaces previously occupied by the dielectric interposer layer 402. Since the thickness of the dielectric spacer 110 spans the space previously occupied by the dielectric interposer layer 402, the thickness of the dielectric spacer is greater than a conductive material thickness formed between adjacent stacked channel regions 102. In other words, the thickness of the dielectric spacer 100 corresponds to the combined thickness of the gate dielectric 106 and the conductive material formed between adjacent channel regions 102.

According to various embodiments, the conductive material may include one or more of polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, and combinations thereof. The gate dielectric layer 106 may be one or more of silicon oxide, silicon nitride, HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, and combinations thereof. In further processing operations, the interlayer dielectric layer 1302 may be removed in the intermediate structure 1800, and a conductive material may be deposited in the resulting spaces to form source/drain electrodes (not shown).

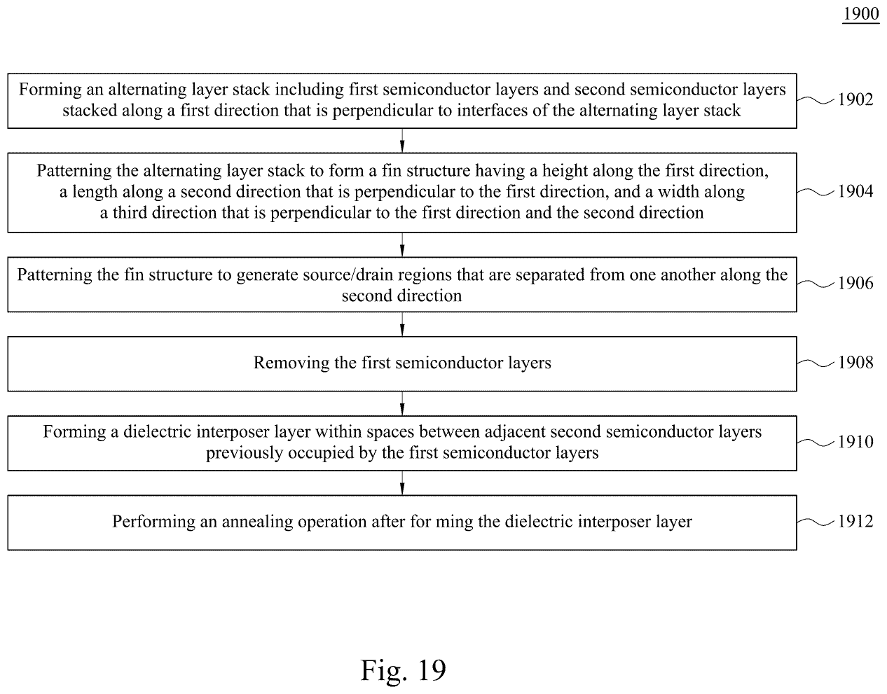

FIG. 19 is a flowchart illustrating operations of a method 1900 of manufacturing a semiconductor device (100, 400b, 400c, 400d), according to various embodiments. According to operation 1902, the method 1900 includes forming an alternating layer stack 501 including first semiconductor layers 101L and second semiconductor layers 102L stacked along a first direction (i.e., the z-direction) that is perpendicular to interfaces of the alternating layer stack 501.

According to operation 1904, the method 1900 includes patterning the alternating layer stack 501 to form a fin structure 202 including a height 502 along the first direction, a length 504 along a second direction (i.e., the x-direction) that is perpendicular to the first direction, and a width 506 along a third direction (i.e., the y-direction) that is perpendicular to the first direction and the second direction. According to operation 1906, the method 1900 includes patterning the fin structure 202 to generate source/drain regions 702 that are separated from one another along the second direction. According to operation 1908, the method 1900 includes removing the first semiconductor layers 101L. According to operation 1910, the method 1900 includes forming a dielectric interposer layer 402 within spaces between adjacent second semiconductor layers 102L previously occupied by the first semiconductor layers 101L. According to operation 1912, the method 1900 includes performing an annealing operation after forming the dielectric interposer layer 402.

According to various embodiments, the method 1900 further includes forming source/drain epitaxial layers 108 in the source/drain regions 702, removing the dielectric interposer layer 402 between the second semiconductor layers 102L such that the second semiconductor layers 102L include stacked channel regions 102 extending between adjacent source/drain epitaxial layers 108, such that the source/drain epitaxial layers 108 are separated from one another along the first direction. The method 1900 further includes forming a gate dielectric layer 106 around each of the stacked channel regions 102 and forming a gate structure 104 that surrounds each of the stacked channel regions 102.

According to various embodiments, the method 1900 further includes performing the annealing operation after forming the source/drain epitaxial layers 108. Further, according to various embodiments, forming the source/drain epitaxial layers 108 is performed after forming the dielectric interposer layer 402. According to further embodiments, the method 1900 further includes, before removing the dielectric interposer layer 402, performing operations including partially etching the dielectric interposer layer 402 to generate cavities 1002 at opposite ends of the dielectric interposer layer 402 facing respective source/drain regions 702, and forming dielectric spacers (110, 100a, 110b, 110c) in the cavities 1002.

According to various embodiments, in forming the gate structure 104, the method 1900 further includes depositing a conductive material between the stacked channel regions 102 such that the conductive material is separated from the stacked channel regions 102 by the gate dielectric layer 106 and is separated from respective source/drain epitaxial layers 108 by the dielectric spacers (110, 100a, 110b, 110c). According to various embodiments, a dielectric spacer thickness is greater than a conductive material thickness.

According to various embodiments, in forming the gate structure 104, the method 1900 further includes forming a sacrificial gate structure 602 over the stacked channel regions 102, patterning the sacrificial gate structure 602 to generate a gate opening 1502 over the stacked channel regions 102, and depositing a conductive material in the gate opening 1502 to thereby form the gate structure 104. According to various embodiments, before removing the dielectric interposer layer 402, first inner edges 1504 of the dielectric spacers (110, 100a, 110b, 110c) are aligned with second inner edges 1506 of the gate opening 1502 before deposition of the conductive material.

According to various embodiments, the conductive material includes one or more of polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, and combinations thereof. According to various embodiments, the gate dielectric layer 106 includes one or more of silicon oxide, silicon nitride, HfO2, HfSiO, HfSiON, HfTaO, HfTiO, HfZrO, zirconium oxide, aluminum oxide, titanium oxide, hafnium dioxide-alumina HfO₂—Al2O3 alloy, and combinations thereof. According to method 1900, each of the stacked channel regions 102 includes a thickness 114 greater than 5 nm. According to method 1900, each of the stacked channel regions 102 includes a thickness variation that is less than 1 nm. According to method 1900, the first semiconductor layers 101L include SiGe and the second semiconductor layers 102L include Si.

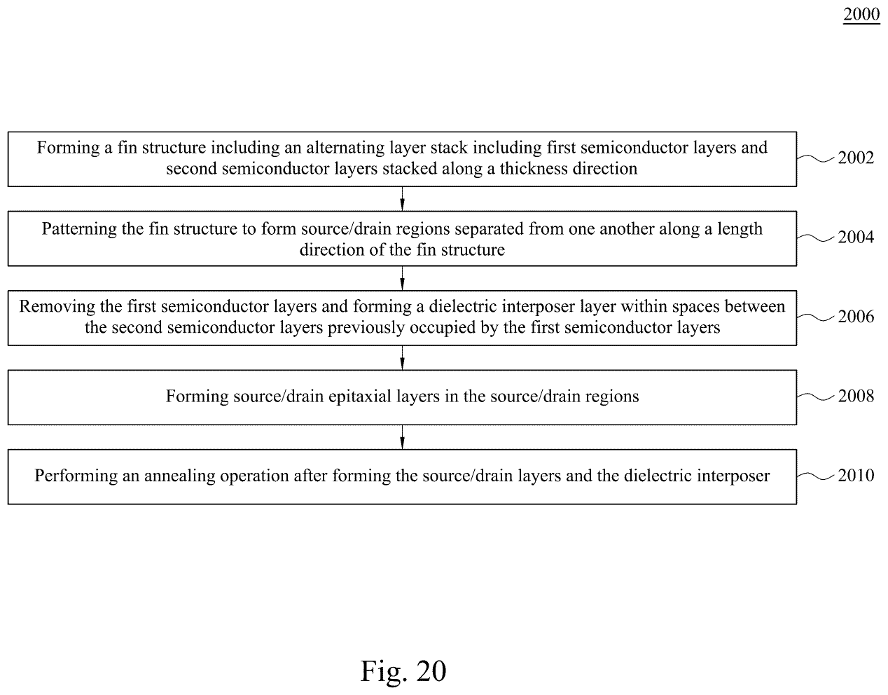

FIG. 20 is a flowchart illustrating operations of a method 2000 of manufacturing a semiconductor device (100, 400b, 400c, 400d), according to various embodiments. According to operation 2002, the method 2000 includes forming a fin structure 202 including an alternating layer stack 501 including first semiconductor layers 101L and second semiconductor layers 102L stacked along a thickness direction (i.e., the z-direction). According to operation 2004, the method 2000 includes patterning the fin structure 202 to form source/drain regions 702 separated from one another along a length direction (i.e., the x-direction) of the fin structure 202. According to operation 2006, the method 2000 includes removing the first semiconductor layers 101L and forming a dielectric interposer layer 402 within spaces between the second semiconductor layers 102L previously occupied by the first semiconductor layers 101L. According to operation 2008, the method 2000 includes forming source/drain epitaxial layers 108 in the source/drain regions 702. According to operation 2010, the method 2000 includes performing an annealing operation after forming the source/drain layers 108 and the dielectric interposer layer 402.

According to various embodiments, forming the source/drain epitaxial layers 108 is performed after forming the dielectric interposer layer 402. According to various embodiments, the method 2000 further includes removing the dielectric interposer layer 402 between the second semiconductor layers 102L such that the second semiconductor layers 102L form stacked channel regions 102 extending between adjacent source/drain epitaxial layers 108, forming a gate dielectric layer 106 around each of the stacked channel regions 102, and forming a gate structure 104 that surrounds each of the stacked channel regions 102. According to various embodiments, the method 2000 further includes forming dielectric spacers (110, 100a, 110b, 110c) on opposite ends of the dielectric interposer layer 402 before removing the dielectric interposer layer 402. According to various embodiments, each of the stacked channel regions 102 includes a thickness 114 greater than 5 nm and each of the stacked channel regions 102 includes a thickness variation that is less than 1 nm.

Referring to all drawings and according to various embodiments of the present disclosure, a semiconductor device (100, 400b, 400c, 400d) is provided. The semiconductor device (100, 400b, 400c, 400d) includes a fin structure 202 including a plurality of semiconductor layers stacked along a thickness 114a direction and configured as stacked channel regions 102, a gate structure 104 formed around each of the stacked channel regions 102, and source/drain epitaxial layers 108 formed on opposite ends of the stacked channel regions 102 along a length direction (i.e., the y-direction) of the fin structure 202.

According to various embodiments, each of the stacked channel regions 102 includes a thickness 114 that is greater than 5 nm, and each of the stacked channel regions 102 has a thickness variation that is less than 1 nm. According to various embodiments, the gate structure 104 further includes a gate dielectric layer 106 formed around each of the stacked channel regions 102 and a conductive material formed around each of the stacked channel regions 102 and separated from the stacked channel regions 102 by the gate dielectric layer 106. According to various embodiments, the semiconductor device (100, 400b, 400c, 400d) further includes dielectric spacers (110, 100a, 110b, 110c) separating the conductive material from the source/drain epitaxial layers 108. According to various embodiments, the conductive material includes one or more of polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, and combinations thereof, and the gate dielectric layer 106 includes one or more of silicon oxide, silicon nitride, HfO2, HfSiO, HfSiON, HfTaO, HfTiO, HfZrO, zirconium oxide, aluminum oxide, titanium oxide, hafnium dioxide-alumina HfO2—Al2O3 alloy, and combinations thereof.

Disclosed embodiments are advantageous by providing a semiconductor device (100, 400b, 400c, 400d) (i.e., a GAA-FET) including stacked channel regions 102 having a high degree of thickness uniformity and smooth interfaces between the stacked channel regions 102 and adjacent portions of a gate structure 104. The high degree of thickness uniformity leads to improved device performance including increased source/drain current and reduced ohmic loss relative to comparative embodiments (e.g., semiconductor device 300a of FIG. 3A) that have reduced-quality interfaces. The superior quality of the stacked channel regions 102 results from a manufacturing process in which a sacrificial semiconductor layer 101L, located between adjacent channel regions 102, is removed and replaced with a dielectric interposer layer 402 before any annealing processes are performed. After subsequent processing operations, including formation of source/drain epitaxial layers 108 followed by annealing operations, the dielectric interposer layer 402 is removed and the gate structure 104 is formed in spaces previously occupied by the dielectric interposer layer 402.

According to various embodiments, a method of manufacturing a semiconductor device is provided. According to various embodiments, the method includes forming an alternating layer stack including first semiconductor layers and second semiconductor layers stacked along a first direction (i.e., the z-direction) that is perpendicular to interfaces of the alternating layer stack. According to various embodiments, the method further includes patterning the alternating layer stack to form a fin structure including a height along the first direction, a length along a second direction (i.e., the x-direction) that is perpendicular to the first direction, and a width along a third direction (i.e., the y-direction) that is perpendicular to the first direction and the second direction. According to various embodiments, the method further includes patterning the fin structure to generate source/drain regions that are separated from one another along the second direction. According to various embodiments, the method further includes removing the first semiconductor layers and forming a dielectric interposer layer within spaces between adjacent second semiconductor layers previously occupied by the first semiconductor layers.

According to various embodiments, the method further includes forming source/drain epitaxial layers in the source/drain regions, removing the dielectric interposer layer between the second semiconductor layers such that the second semiconductor layers include stacked channel regions extending between adjacent source/drain epitaxial layers, which are separated from one another along the first direction. The method further includes forming a gate dielectric layer around each of the stacked channel regions, and forming a gate structure that surrounds each of the stacked channel regions.

According to various embodiments, the method further includes performing an annealing operation after forming the source/drain epitaxial layers. Further, according to various embodiments, forming the source/drain epitaxial layers is performed after forming the dielectric interposer layer. According to further embodiments, the method further includes, before removing the dielectric interposer layer, performing operations including partially etching the dielectric interposer layer to generate cavities at opposite ends of the dielectric interposer layer facing respective source/drain regions, and forming dielectric spacers in the cavities.

According to various embodiments, in forming the gate structure, the method further includes depositing a conductive material between the stacked channel regions such that the conductive material is separated from the stacked channel regions by the gate dielectric layer and is separated from respective source/drain epitaxial layers by the dielectric spacers. According to various embodiments, a dielectric spacer thickness is greater than a conductive material thickness.

According to various embodiments, in forming the gate structure, the method further includes forming a sacrificial gate structure over the stacked channel regions, patterning the sacrificial gate structure to generate a gate opening over the stacked channel regions, and depositing a conductive material in the gate opening to thereby form the gate structure. According to the method, before removing the dielectric interposer layer, first inner edges of the dielectric spacers are aligned with second inner edges of the gate opening before deposition of the conductive material.

According to various embodiments, the conductive material includes one or more of polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, and combinations thereof. According to various embodiments, the gate dielectric layer includes one or more of silicon oxide, silicon nitride, HfO2, HfSiO, HfSiON, HfTaO, HfTiO, HfZrO, zirconium oxide, aluminum oxide, titanium oxide, hafnium dioxide-alumina HfO2—Al2O3 alloy, and combinations thereof. According to the method, each of the stacked channel regions includes a thickness greater than 5 nm. According to various embodiments, each of the stacked channel regions includes a thickness variation that is less than 1 nm. According to various embodiments, the first semiconductor layers include SiGe and the second semiconductor layers include Si.

According to various embodiments, a further method of manufacturing a semiconductor device is provided. The method includes forming a fin structure including an alternating layer stack including first semiconductor layers and second semiconductor layers stacked along a thickness direction (i.e., the z-direction). The method further includes patterning the fin structure to form source/drain regions separated from one another along a length direction (i.e., the x-direction) of the fin structure. The method includes removing the first semiconductor layers and forming a dielectric interposer layer within spaces between the second semiconductor layers previously occupied by the first semiconductor layers. The method further includes forming source/drain epitaxial layers in the source/drain regions.

According to various embodiments, the method further includes performing an annealing operation after forming the source/drain epitaxial layers, forming the source/drain epitaxial layers after forming the dielectric interposer layer, and removing the dielectric interposer layer between the second semiconductor layers such that the second semiconductor layers form stacked channel regions extending between adjacent source/drain epitaxial layers. According to various embodiments, the method further includes forming a gate dielectric layer around each of the stacked channel regions, and forming a gate structure that surrounds each of the stacked channel regions. According to various embodiments, the method further includes forming dielectric spacers on opposite ends of the dielectric interposer layer before removing the dielectric interposer layer. According to various embodiments, each of the stacked channel regions includes a thickness greater than 5 nm and each of the stacked channel regions includes a thickness variation that is less than 1 nm.

According to various embodiments, a semiconductor device is provided. The semiconductor device includes a fin structure including a plurality of semiconductor layers stacked along a thickness direction and configured as stacked channel regions, a gate structure formed around each of the stacked channel regions, and source/drain epitaxial layers formed on opposite ends of the stacked channel regions along a length direction (i.e., the y-direction) of the fin structure.

According to various embodiments, each of the stacked channel regions includes a thickness greater than 5 nm, and each of the stacked channel regions includes a thickness variation that is less than 1 nm. According to various embodiments, the gate structure further includes a gate dielectric layer formed around each of the stacked channel regions and a conductive material formed around each of the stacked channel regions and separated from the stacked channel regions by the gate dielectric layer. According to various embodiments, the semiconductor device further includes dielectric spacers separating the conductive material from the source/drain epitaxial layers. According to various embodiments, the conductive material includes one or more of polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, and combinations thereof, and the gate dielectric layer includes one or more of silicon oxide, silicon nitride, HfO2, HfSiO, HfSiON, HfTaO, HfTiO, HfZrO, zirconium oxide, aluminum oxide, titanium oxide, hafnium dioxide-alumina HfO2—Al2O3 alloy, and combinations thereof.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device, comprising:
forming an alternating layer stack comprising first semiconductor layers and second semiconductor layers stacked along a first direction that is perpendicular to interfaces of the alternating layer stack;
patterning the alternating layer stack to form a fin structure comprising a height along the first direction, a length along a second direction that is perpendicular to the first direction, and a width along a third direction that is perpendicular to the first direction and the second direction;
patterning the fin structure to generate source/drain regions that are separated from one another along the second direction;
removing the first semiconductor layers;
forming a dielectric interposer layer within spaces between adjacent second semiconductor layers previously occupied by the first semiconductor layers; and
performing an annealing operation after forming the dielectric interposer layer.

2. The method of claim 1, further comprising:
forming source/drain epitaxial layers in the source/drain regions;
removing the dielectric interposer layer between the second semiconductor layers such that the second semiconductor layers comprise stacked channel regions extending between adjacent source/drain epitaxial layers and separated from one another along the first direction;
forming a gate dielectric layer around each of the stacked channel regions; and
forming a gate structure that surrounds each of the stacked channel regions.

3. The method of claim 2, further comprising:
performing the annealing operation after forming the source/drain epitaxial layers,
wherein forming the source/drain epitaxial layers is performed after forming the dielectric interposer layer.

4. The method of claim 2, further comprising:
before removing the dielectric interposer layer, performing operations comprising:
partially etching the dielectric interposer layer to generate cavities at opposite ends of the dielectric interposer layer facing respective source/drain regions; and
forming dielectric spacers in the cavities.

5. The method of claim 4, wherein forming the gate structure further comprises:
depositing a conductive material between the stacked channel regions such that the conductive material is separated from the stacked channel regions by the gate dielectric layer and is separated from respective source/drain epitaxial layers by the dielectric spacers.

6. The method of claim 4, wherein a dielectric spacer thickness is greater than a conductive material thickness.

7. The method of claim 4, wherein forming the gate structure further comprises:
forming a sacrificial gate structure over the stacked channel regions;
patterning the sacrificial gate structure to generate a gate opening over the stacked channel regions; and
depositing a conductive material in the gate opening to thereby form the gate structure,
wherein, before removing the dielectric interposer layer, first inner edges of the dielectric spacers are aligned with second inner edges of the gate opening before deposition of the conductive material.

8. The method of claim 7, wherein the conductive material comprises one or more of polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, and combinations thereof.

9. The method of claim 2, wherein the gate dielectric layer comprises one or more of silicon oxide, silicon nitride, HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, and combinations thereof.

10. The method of claim 2, wherein each of the stacked channel regions comprises a thickness that ranges from 5 nm to 10 nm.

11. The method of claim 2, wherein each of the stacked channel regions comprises a thickness variation that is less than 1 nm.

12. The method of claim 1, wherein the first semiconductor layers comprise SiGe and the second semiconductor layers comprise Si.

13. A method of forming a semiconductor device, comprising:
forming a fin structure comprising an alternating layer stack comprising first semiconductor layers and second semiconductor layers stacked along a thickness direction;
patterning the fin structure to form source/drain regions separated from one another along a length direction of the fin structure;
removing the first semiconductor layers;
forming a dielectric interposer layer within spaces between the second semiconductor layers previously occupied by the first semiconductor layers;
forming source/drain epitaxial layers in the source/drain regions; and
performing an annealing operation after forming the source/drain epitaxial layers and the dielectric interposer layer.

14. The method of claim 13, wherein forming the source/drain epitaxial layers is performed after forming the dielectric interposer layer.

15. The method of claim further comprising:
removing the dielectric interposer layer between the second semiconductor layers such that the second semiconductor layers form stacked channel regions extending between adjacent source/drain epitaxial layers;
forming a gate dielectric layer around each of the stacked channel regions; and
forming a gate structure that surrounds each of the stacked channel regions.

16. The method of claim 15, further comprising:
forming dielectric spacers on opposite ends of the dielectric interposer layer before removing the dielectric interposer layer.

17. The method of claim 15, wherein:
each of the stacked channel regions comprises a thickness greater than 5 nm; and
each of the stacked channel regions comprises a thickness variation that is less than 1 nm.

18. A semiconductor device, comprising:
a fin structure comprising a plurality of semiconductor layers stacked along a thickness direction and configured as stacked channel regions;
a gate structure formed around each of the stacked channel regions; and
source/drain epitaxial layers formed on opposite ends of the stacked channel regions along a length direction of the fin structure,
wherein:
each of the stacked channel regions comprises a thickness greater than 5 nm; and
each of the stacked channel regions comprises a thickness variation that is less than 1 nm.

19. The semiconductor device of claim 18, wherein the gate structure further comprises:
a gate dielectric layer formed around each of the stacked channel regions; and
a conductive material formed around each of the stacked channel regions and separated from the stacked channel regions by the gate dielectric layer,
wherein the semiconductor device further comprises dielectric spacers separating the conductive material from the source/drain epitaxial layers.

20. The semiconductor device of claim 19, wherein:
the conductive material comprises one or more of polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, and combinations thereof; and
the gate dielectric layer comprises one or more of silicon oxide, silicon nitride, HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, and combinations thereof.
